(19) United States
(12) Patent Application Publication
(10) Pub. No.: US 2013/0027112 A1
(43) Pub. Date: Jan. 31, 2013

(54) INDUCTOR

(71) Applicants: Yen-Wei Hsu, Taipei (TW); Whei-Chyou Wu, Fremont, CA (US)

(72) Inventors: Yen-Wei Hsu, Taipei (TW); Whei-Chyou Wu, Fremont, CA (US)

(21) Appl. No.: 13/193,620

(22) Filed: Jul. 29, 2011

(51) Int. Cl. H03K 17/56; H01F 17/04; H02K 1/12; H01F 27/24

(52) U.S. Cl. 327/419; 336/212; 336/221; 310/254.1

(57) ABSTRACT

This invention relates to an inductor, more particularly, to an inductor with variable inductances.

### BACKGROUND OF THE INVENTION

1. Field of the Invention

This invention relates to an inductor, more particularly, to an inductor with variable inductances.

2. Description of Related Art

Conventionally, there are a number of known voltage regulating circuits, for example, a boost circuit for boosting voltage level and a buck circuit for reducing voltage level. FIG. 1b, FIG. 1c and FIG. 1e have respectively shown a first boost circuit, a second boost circuit and a blocking oscillator. FIG. 1d has shown a buck circuit.

FIG. 1b has shown an electrical power source such as a dc power source 101, an inductor 102, a switch such as a power transistor 103, a PWM controller 104 for controlling the on/off switching of the power transistor 103 and a loading 106. The dc power source 101, the inductor 102 and the power transistor 103 are electrically connected in series with each other and the loading 106 is electrically connected to a first location 1091 between the dc power source 101 and the inductor 102 or a high side of the inductor 102. Please note that a diode 106 is for keeping current flow in one direction.

FIG. 1c is based on FIG. 1b with the loading 106 electrically connected to a second location 1092 between the inductor 102 and the power transistor 103 or a low side of the inductor 102.

FIG. 1d has shown a buck circuit which comprises a dc power source 101, an inductor 102, a switch such as a power transistor 103, a diode 106 for keeping current in one direction, and a loading 106 electrically connected in series with each other. A PWM controller 104 is for controlling the on/off switching of the power transistor 103.

FIG. 1e has shown a known blocking oscillator which can be divided into a first circuit 128 marked by a dotted block and a second circuit not in the first circuit coupling the first circuit 128. The second circuit formed by an electrical power source 120, a second inductor 124, a second resistor 122 which is the resistance of the second inductor 124, a switch such as a power transistor 125 and a driven loading 127 electrically connected to a low side of the second inductor 124. The electrical power source 120, the second inductor 124, the power transistor 125 are electrically connected in series with each other.

Please note that the second circuit of the blocking oscillator of FIG. 1e is the second boost circuit of FIG. 1c.

The first circuit 128 formed by a first resistor 121, a first inductor 123 forming a transformer with the second inductor 124 as a disturbance to the blocking oscillator, and a capacitor 126 electrically connecting with the second circuit to oscillate the power transistor 125 so that the power transistor 125 oscillated by the first circuit 128 can be viewed as a self-excitation switch and the blocking oscillator of FIG. 1e is a self-excitation oscillator. The on/off switching of the power transistor of FIGS. 1b, 1c and 1d is controlled by a “given signal” from the PWM controller, but the power transistor 125 of the second circuit of FIG. 1e oscillates by the first circuit 128 electrically connecting the second circuit so that the power transistor 125 of FIG. 1e is a self-excitation switch.

Those circuits above have a “switching circuit” in common, an electrical power source for providing an electrical energy, an inductor for temporarily storing magnetic energy converted from the electrical energy of the electrical power source, and a frequency modulator for providing frequency-modulation to the switching circuit electrically connected in series with each other.

The switching circuit describes converting an electrical energy of the power source into a magnetic energy temporarily stored in the inductor and releasing the magnetic energy temporarily stored in the inductor into current controlled by the oscillation of the frequency-modulator. By using the second boost circuit of FIG. 1c as an example, when the power transistor 103 is in close state (the power transistor is on), a current from the power source 101 flowing through the switching circuit magnetizes the inductor 102 coverting an electrical energy from the power source 101 into a magnetic energy temporarily stored in the inductor 102; and when the power transistor 103 is in open state (the power transistor is off), current from the power source 101 stops and the magnetic energy temporarily stored in the inductor 102 will be immediately released in the form of a current for driving the loading 105. Obviously, converting the energy from the power source 101 into the magnetic energy stored in the inductor 102 and releasing the magnetic energy temporalily stored in the inductor 102 into current for driving the loading 105 is realized by the switchings of the power transistor 103. For example, if the power transistor 103 is always on, then the magnetic energy converted by the electrical energy of the power source 101 will be continuously stored in the inductor 102 against releasing until the power transistor 103 is turned off.

The switching circuit can be expressed in a general form as shown in FIG. 1f which comprises an electrical power source 151 for providing electrical energy, a first inductor 152 for temporarily storing magnetic energy converted by the electrical energy from the electrical power source 151, and a frequency modulator 153 for frequency-modulating the switching circuit electrically connected in series with each other.

The frequency modulator is not limited, for example, it can be the power transistor 103 controlled by the PWM controller 104 as shown in FIG. 1b, 1c or 1d or it can be the self-excitation switch as shown in FIG. 1e. The electrical energy of the electrical power source can be converted into the magnetic energy temporarily stored in the inductor and the magnetic energy temporarily stored in the inductor can be immediately released into current by the oscillation of the frequency modulator. A loading driven by the switching circuit can be electrically connected to different locations of the switching circuit, for example, a first location 1512 between the electrical power source 151 and the first inductor 152 as the first boost circuit shown in FIG. 1b, a second location 1523 between the first inductor 152 and the frequency-modulator 153 as the second boost circuit shown in FIG. 1c, a third location 1531 at the low side of the frequency-modulator 153 as the buck circuit shown in FIG. 1d. Or, a loading 1541 can be driven by a second inductor 154 forming a transformer with the first inductor 152 as shown in FIG. 1f.

The switching circuit has characterized a conversion between electrical energy and magnetic energy so that the performance of the conversion is critical. Pulling as much and fast as possible the electrical energy from the electrical power source into magnetic energy temporarily stored in the inductor and releasing as much and fast as possible the magnetic energy stored in the inductor into current for satisfying loading are critical. For example, if the electrical power source is a solarcell, which is an unknown and a high frequency power source, then pulling as much and fast as possible the electrical energy from the solarcell into the magnetic energy is critical to the performance of the solarcell.

The performance of the conversion between electrical energy and magnetic energy of a switching circuit decides the performance of the switching circuit, and the performance of the switching circuit decides the performance of circuits based on the switching circuit. Conventionally, once the number of turns of coils winding on an magnetic core, the diametric of the coils, the cross-section area of the magnetic core, and the material made of the magnetic core are decided, the inductance of the inductor can be viewed as a constant. Constant inductance of an inductor has decided the current from the power source to flow through the switching circuit. Intuitively, another way trying to increase the current with constant inductance of an inductor of a switching circuit is to increase the frequency of the frequency modulator, but speeding the frequency of the frequency-modulator will increase the impedance of the inductor described by z=2πfL to further limit the current to flow through the switching circuit.

Constant inductance of the inductor and limited current of the traditional switching circuit provides very bad conversion between electrical energy and magnetic energy and bad impedance-matching between the electrical power source and the loading, especially the impedance-matching between an unknown power source such as a solarcell or battery and an unknown loading with variable impedances.

Those drawbacks are the serious problems to the traditional switching circuit and the circuits based on the switching circuit such as the first boost circuit of FIG. 1b, the second boost circuit of FIG. 1c, the buck circuit of FIG. 1d, or the blocking oscillator of FIG. 1e.

The drawbacks of constant inductance of an inductor are also the problems to the traditonal transformer, eletric motor and electrical generator.

FIG. 2a has shown a traditional transformer. A primary coil 2011 and a secondary coil 2012 are wound around a magnetic core 201 and most of the magnetic flux passes through both the primary coil 2011 and the secondary coil 2012. Once the number of turns of each coil, the diameter of each coil, the cross-section area of the magnetic core, and the material made of the magnetic core are decided, the inductance of the inductor can be viewed as a constant. Constant inductance has decided the current induced on the secondary coil or electrical output power.

An electric motor converts electrical energy into mechanical energy. FIG. 2b can be used to refer to an electric motor core having a stator core 231, a rotor core 232 and a rotational axle 233 fixed on the rotor core 232 in top view.

The stator core 231 has a plurality of poles respectively wound by a conductive coil, for example, two poles 2311 and 2312 are respectively wound by a conductive coil as shown in FIG. 2b. The rotor core 232 has a plurality of poles respectively wound by a conductive coil, for example, three poles 2321, 2322 and 2323 are respectively wound by a conductive coil as shown in FIG. 2b. The conductive coils of the stator core 231 are electrically connected in series with each other and the conductive coils of the rotor core 232 are electrically connected in series with each other. The conductive coils of the stator core 231 and the conductive coils of the rotor core 232 can receive a same current source or different current sources to respectively magnetize the stator core 231 and the rotor core 232.

For the purpose of convenience, assuming the conductive coils of the stator core 231 and the conductive coils of the rotor core 232 receive a same current source. Equation

$$τ = \frac{1}{2} {i}^{2} \frac{d L ( θ )}{d θ}$$

expresses a torque τ is proportional to i² or τ∝ i², of which i is a current flows through the conductive coils of the stator core 231 and the rotor core 232, dθ describes phase differences between poles respectively of the stator core 231 and the rotor core 232, and L is the inductance of the conductive coils.

For obtaining a bigger power relates to a bigger size core, but the bigger size core relates to a bigger inductance of a conductive coil winding around the core. Bigger inductance leads to bigger impedance described by

$$\begin{matrix}Z = j {X}_{L} \\ = j 2 π fL\end{matrix}$$

Trying to enlarge the diameter of the conductive coil and decrease the number of turns of the conductive coil winding on the core won't do much help to increase current flowing through the conductive coil.

Once the number of turns of coils winding on the stator and rotor cores, the diameter of the conductive coils, the cross-section area of the stator and rotor cores, and the materials made of the stator core 231 and rotor core 232 are decided, their correspondent inductances can be viewed as a constant. Constant inductances of the stator core 231 and the rotor core 232 have decided the current to flow through the conductive coils respectively of the stator core 231 and the rotor core 232, which has decided the torque τ between the stator core 231 and the rotor core 232 as described by equation

$$τ = \frac{1}{2} {i}^{2} \frac{d L ( θ )}{d θ}$$

Trying to run the electric motor at higher frequency, the current will be further limited by an increasing impedance according to

$$\begin{matrix}Z = j {X}_{L} \\ = j 2 π fL\end{matrix}$$

to limit its output torque τ. This traditional electric motor can only output a reasonable torque τ at low speed and its output torque becomes very small at high speed. An electric motor having a big torque output and running at higher frequency is being pursued. The drawbacks described above are the serious and long-term unsolved problems to the traditional electric motor.

The drawing of FIG. 2b can be also used to refer to an electric generator core. An electric generator is a device that converts mechanical energy into electrical energy. For the purpose of convenience, assuming the conductive coils winding around the stator core 231 and the conductive coils winding around the rotor core 232 are respectively called as stator coil and rotor coil. If an input current flowing through the stator coil or the rotor coil magnetizes its correspondent winding core and a relative motion takes place between the stator core 231 and the rotor core 232, then an output current will be induced on the stator coil or rotor coil not being flowed by the input current. Constant inductances of the stator core 231 and the rotor core 232 described in the electric motor core above are also the problems to the traditional electric generator.

Intuitionally, for a big and constant inductance, trying to get a bigger output current by speeding the relative motion between the stator core 231 and the rotor core 232 will increase the impedance according to Z=jX_{L}=j2πfL to further limit the input current resulting in limiting the output current. Trying to modulate the frequency of the input current with that of the relative motion will have a lot bigger impedance because the total frequency is the multiplication of the frequency of the input current and the frequency of the relative motion between the stator core 231 and the rotor core 232, which will further limit the input current resulting in further limiting the output current such that trying to modulate the frequency of the input current with that of the relative motion is almost impossible for the traditional electric generator. That's why the traditional electric generator only output current in a single waveform. An electric generator having a big output current in a multi-waveform is a goal to be pursued. The drawbacks described above are the serious and long-term unsolved problems to the traditional electric generator.

### BRIEF SUMMARY OF THE INVENTION

The invention provides an inventive magnetic core and an inventive inductor with variable inductances to remedy the drawbacks of the traditional transformer core, electric motor core, electric generator core, switching circuit, and circuits constructed by the switching circuit revealed in the background information section above.

### BRIEF DESCRIPTION OF THE SEVERAL VIEWS OF THE DRAWINGS

FIG. 1a has shown an embodiment of a typical switching circuit;

FIG. 1b has shown a first boost circuit;

FIG. 1c has shown a second boost circuit;

FIG. 1d has shown a traditional buck circuit;

FIG. 1e has shown a traditional blocking oscillator circuit;

FIG. 1f has shown a switching circuit in a general form;

FIG. 2a has shown a traditional transformer;

FIG. 2b has shown a rotor core and a stator core of an electric motor core or an electric generator core in top view;

FIG. 3 has shown a plurality of inductors electrically conneced in parallel with each other;

FIG. 4 has shown a plurality of inductors electrically conneced in series with each other;

FIG. 5 has shown two on-core inductors with different saturation levels electrically conneced in series;

FIG. 6 has shown two on-core inductors with different saturation levels electrically conneced in series and the two on-core inductors are within in magnetically interactive distance with each other;

FIG. 7 has shown an embodiment of five on-core inductors electrically conneced in series with each other and the five on-core inductors have different saturation levels from each other;

FIG. 8a has shown an inductive circuit;

FIG. 8b has shown a current-time characteristic of the inductive circuit of FIG. 8a;

FIG. 9a has shown a “serial on-core-inductor assembly” formed by a plurality of on-core coils electrically conneced in series with each other and the plurality of on-core coils have different saturation levels from each other;

FIG. 9b has shown a “parallel on-core-inductor assembly” formed by n “serial on-core-inductor assemblies” electrically connected in parallel with each other;

FIG. 10 has shown a “parallel-serial on-core-inductor assembly” formed by a “serial on-core-inductor assembly” and a “parallel on-core-inductor assembly” electrically connected in series with each other;

FIG. 11a has shown a multiple-magnetic-conductor magnetic core wound by a conductive coil and the multiple-magnetic-conductor magnetic core has n magnetic conductors having different saturation levels from each other for n is an integer larger than one;

FIG. 11b has shown a multiple-laminal-magnetic-conductor magnetic core wound by a conductive coil and the multiple-laminal-magnetic-conductor magnetic core has n laminal magnetic conductors having different saturation levels from each other for n is an integer larger than one;

FIG. 11c has shown a multiple-laminal-magnetic-conductor magnetic core having 13 laminal magnetic conductors;

FIG. 12a has shown the multiple-laminal-magnetic-conductor magnetic core of FIG. 11b in top view as an I-shaped core;

FIG. 12b has shown the multiple-laminal-magnetic-conductor magnetic core of FIG. 11b in top view as a ring-shaped core;

FIG. 12c has shown the multiple-laminal-magnetic-conductor magnetic core of FIG. 11b in top view as a C-shaped core;

FIG. 13 has shown an embodiment of a multiple-laminal-magnetic-conductor magnetic core of which at least a portion of a side of a laminal magnetic conductor of the multiple-laminal-magnetic-conductor magnetic core facing adjacent laminal magnetic conductor may have an area for contacting cooling matter such as air or cooling fluid for better heat dissipation capability;

FIG. 14 has shown an unsaturable “serial on-core-inductor assembly” formed by a saturable multiple-laminal-magnetic-conductor magnetic core and an unsaturable on-core inductor electrically connected in series;

FIG. 15 has shown the second boost circuit of FIG. 1c with the inductor substituted by a multiple-laminal-magnetic-conductor inductor;

FIG. 16 has shown the second boost circuit of FIG. 1c with the inductor substituted by the unsaturable “serial on-core-inductor assembly” of FIG. 14;

FIG. 17a has shown an inventive transformer in top view;

FIG. 17b has shown the inventive transformer of FIG. 17a in side view;

FIG. 18 has shown an inventive stator core and rotor core in side view of the electric motor core referred to FIG. 2b;

FIG. 19 has shown a plurality of different H-B loop patterns; and

FIG. 20 has shown the inductor of the switching circuit of FIG. 1f respectively substituted by a “non-zero-inductance serial on-core-inductor assembly”, a “non-zero-inductance parallel on-core-inductor assembly”, a “non-zero-inductance parallel-serial on-core-inductor assembly”, a “non-zero-inductance multiple-magnetic-conductor inductor” or a “non-zero-inductance multiple-laminal-magnetic-conductor inductor”.

### DETAILED DESCRIPTION OF THE INVENTION

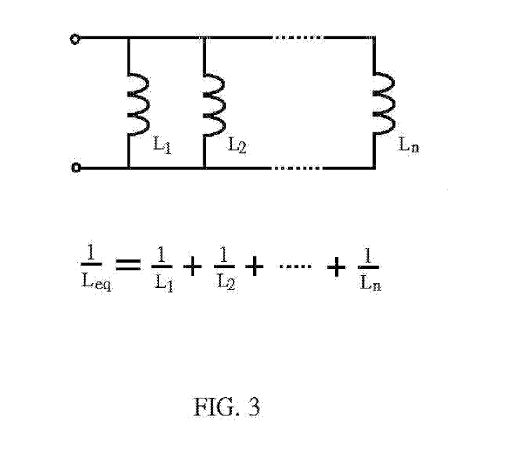

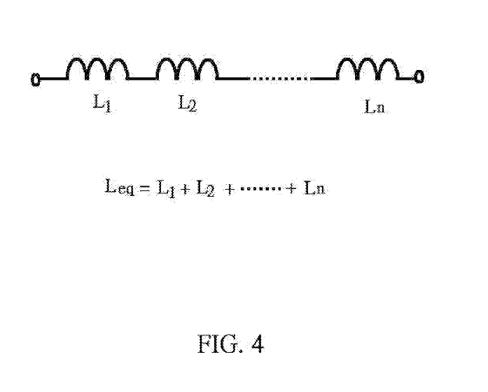

According to the revelations in the background information section, an inventive magnetic core and an inventive inductor with variable inductances are revealed to remedy the drawbacks explained in the traditional transformer, electric motor core, electric generator core, switching circuit and circuits based on the switching circuit. An inductor with variable inductances can also be called variable inductor in the present invention. Before going further into a detailed description of the invention, inductors electrically connected in parallel and in series are reviewed first and respectively shown in FIG. 3 and FIG. 4. FIG. 3 has shown a plurality of inductors electrically connected in parallel with each other and their equivalent inductance L_{eq} is shown by an equation

$$\frac{1}{Leq} = \frac{1}{{L}_{1}} + \frac{1}{{L}_{2}} … + \frac{1}{{L}_{n}}$$

FIG. 4 has shown a plurality of inductors electrically connected in series with each other and their equivalent inductance L_{eq} is shown by an equation

L_{eq}=L₁+L₂+ . . . +Lₙ

For example, if three inductors respectively having L₁, L₂ and L₃ are electrically connected in series with each other, then their equivalent inductance is

L_{eq}=L₁+L₂+L₃

Please note that L_{eq} will drop if any one of L₁, L₂ and L₃ becomes zero, for example, if L₃ becomes zero, then L_{eq}=L₁+L₂.

For another example, if three inductors respectively having L₁, L₂ and L₃ are electrically connected in parallel with each other, then their equivalent inductance is

$$\frac{1}{Leq} = \frac{1}{{L}_{1}} + \frac{1}{{L}_{2}} + \frac{1}{{L}_{3}}$$

$$or$$

$${L}_{eq} = \frac{{L}_{1} {L}_{2} {L}_{3}}{{L}_{1} {L}_{2} + {L}_{3} {L}_{1} + {L}_{3} {L}_{1}}$$

after some calculations. Please note that L_{eq}=0 if any one of L₁, L₂ and L₃ becomes zero because

L₁L₂L₃=0=L_{eq}

according to

$${L}_{eq} = \frac{{L}_{1} {L}_{2} {L}_{3}}{{L}_{1} {L}_{2} + {L}_{3} {L}_{1} + {L}_{3} {L}_{1}}$$

An inductor can be formed by a conductive coil winding on a magnetic core. For the purpose of convenience, a conductive coil winding on a magnetic core can be called “on-core inductor” in the present invention. For the purpose of convenience, a conductive coil can be called a “coil” in short in the present invention. A magnetic core of an “on-core inductor” is not limited in any particular size, shape, structure and material made of it.

Seen in many magnetic materials, saturation can be observed in a hysteresis curve or B-H loop pattern of a material. As magnetic field H increases, the flux density B approaches a maximum value asymptotically, the saturation level for the material. A magnetic permeability (or permeability in short) is defined by

$$μ = \frac{B}{H}$$

of which μ describes the slope of the B/H in B-H loop pattern. When a material in saturation, the flux density B presents no change or dB=0.

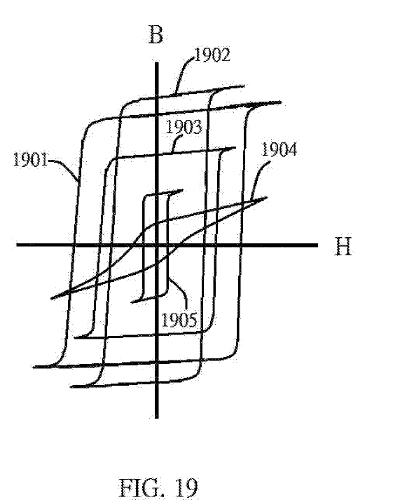

Different materials have different saturation levels or different B-H loop patterns as shown in FIG. 19, for example, the saturation of iron alloys can be high to 1.6˜2.2 teslas and ferrites saturate can be as low as 0.2˜0.5 teslas. FIG. 19 has shown different B-H loop patterns 1901, 1902, 1903, 1904 and 1905. A “magnetization” on an “on-core inductor” includes a current flowing through a conductive coil of the “on-core inductor”, a magnetic field within a magnetically interactive distance in phase with a magnetic core of the “on-core inductor”, or the combinations of thereof. The magnetic field can be a static magnet or produced by a current flowing through an another coil.

Some basic properties of an on-core inductor are reviewed first. When a magnetic core of an on-core inductor goes into magnetic saturation the flux density presents no change or dB=0. According to equation

$$B = \frac{φ}{A} ,$$

dB=0 means dφ=0. According to equation

$$L = N \frac{d φ}{d i} ,$$

dφ=0, leads to L=0, in other words, when a magnetic core of an on-core inductor goes into magnetic saturation the inductance of the on-core inductor becomes zero or L=0. L=0 means that the impedance of the on-core inductor is disappeared as a short circuit at a time of the magnetic saturation of the magnetic core of the on-core inductor.

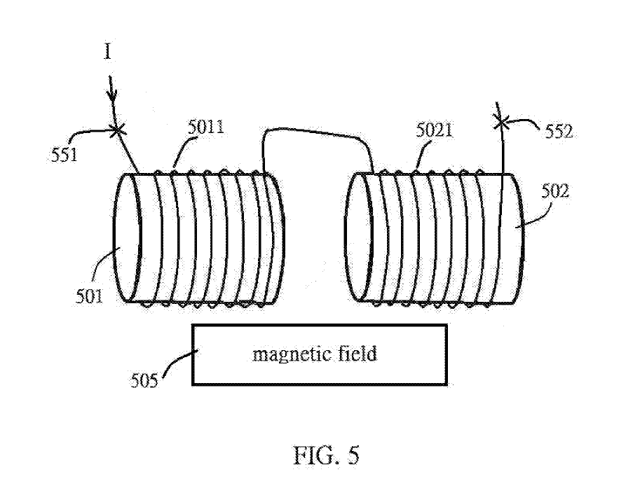

FIG. 5 has shown two on-core inductors electrically connected in series. A first on-core inductor having an inductance L₁ is formed by a first conductive coil 5011 and a first magnetic core 501 wound by the first conductive coil 5011 and a second on-core inductor having an inductance L₂ is formed by a second conductive coil 5021 and a second magnetic core 502 wound by the second conductive coil 5021.

The number of turns respectively of the first conductive coil 5011 on the first magnetic core 501 and the second conductive coil 5021 on the second magnetic core 502 may be different from each other. The first conductive coil 5011 and the second conductive coil 5021 may be different from each other in material, diameter, size, conductivity, and the number of turns. The first magnetic core 501 and the second magnetic core 502 may be different from each other in material, shape, size, structure, and saturation level. The first magnetic core 501 and the second magnetic core 502 are not limited to any particular magnetic cores.

Each of the first coil 5011 and the second coil 5021 has two ends such that a first end 551 and a second end 552 are formed by the serial connection of the first coil 5011 and the second coil 5021.

Assuming the first magnetic core 501 and the second magnetic core 502 are not within a magnetically interactive distance with each other by a magnetization and assuming the first magnetic core 501 and the second magnetic core 502 have different magnetic saturation levels from each other, for example, assuming the first magnetic core 501 has lower saturation level than that of the second magnetic core 502. At a first instance with both the two magnetic cores before saturation, the equivalent inductance measured between the first end 551 and the second end 552 is L_{eq}=L₁+L₂ and its associated impedance is expressed by

$$\begin{matrix}Z = j {X}_{L} \\ = j 2 π f ( {L}_{1} + {L}_{2} )\end{matrix}$$

and at a second instance with the first magnetic core 501 first into the saturation, the equivalent inductance measured between the first end 551 and the second end 552 is L_{eq}=L₂ with L₁ becomes zero and its associated impedance is expressed by

$$\begin{matrix}Z = j {X}_{L} \\ = j 2 π f ( {L}_{2} )\end{matrix}$$

Obviously, the inductance and impedance measured between the first end 551 and the second end 552 after the saturation of the first magnetic core 501 change to drop.

If the first magnetic core 501 is saturated and the second magnetic core 502 is not saturated by a magnetization such as a current flowing through the first end 551 and the second end 552 or a magnetic field 505 in a magnetically interactive distance in phase with the first magnetic core 501 and the second magnetic core 502, then the equivalent inductance measured between the first end 551 and the second end 552 has a non-zero value by the magnetization. If both the first magnetic core 501 and the second magnetic core 502 are saturated by the magnetization, then the equivalent inductance measured between the first end 551 and the second end 552 will drop to zero by the magnetization.

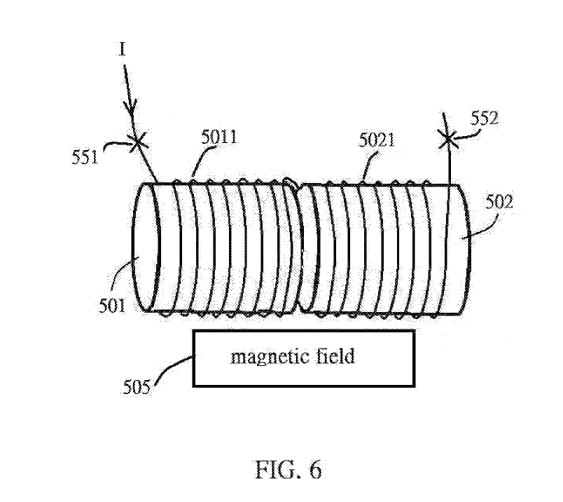

Now, the first magnetic core 501 and the second magnetic core 502 shown in FIG. 5 are disposed closer within a magnetically interactive distance in phase with each other as shown in FIG. 6. The first magnetic core 501 and the second magnetic core 502 by a magnetization may interactively intensify the flux density with each other, which may contribute to an earlier saturation.

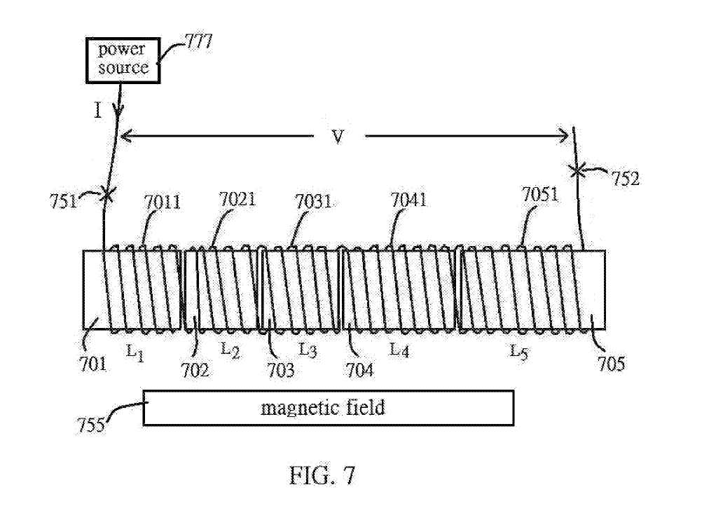

FIG. 5 and FIG. 6 have demonstrated two on-core inductors. More on-core inductors electrically connected in series with each other will be discussed. FIG. 7 has shown five on-core inductors respectively having inductance L₁, L₂, L₃, L₄ and L₅ are electrically connected in series with each other.

FIG. 7 has shown five coils 7011, 7021, 7031, 7041 and 7051 respectively winding around five magnetic cores 701, 702, 703, 704 and 705 are electrically connected in series with each other and the five magnetic cores 701, 702, 703, 704 and 705 having different saturation levels from each other for producing saturations one by one in a row by a magnetization such as a current flowing through the five coils 7011, 7021, 7031, 7041 and 7051 or a magnetic field 755 in a magnetically interactive distance in phase with the five magnetic cores 701, 702, 703, 704 and 705. Please note that a first end 751 and a second end 752 are formed by the serial connections of the five coils 7011, 7021, 7031, 7041 and 7051. The five coils 7011, 7021, 7031, 7041 and 7051 may be different from each other in material, diameter, size, conductivity, and the number of turns. The five magnetic cores 701, 702, 703, 704 and 705 may be different from each other in material, shape, saturation level, structure and size.

Before any saturation of the five magnetic cores, the five on-core inductors respectively have inductance L₁, L₂, L₃, L₄ and L₅ and the equivalent inductance measured between the first end 751 and the second end 752 is

L_{eq}=L₁+L₂+L₃+L₄+L₅

and its associated impedance can be expressed by

$$\begin{matrix}Z = j {X}_{L} \\ = j 2 π f ( {L}_{1} + {L}_{2} + {L}_{3} + {L}_{4} + {L}_{5} )\end{matrix}$$

When L_{eq} drops, the associated impedance z drops.

When a magnetization acting on the five on-core inductors of FIG. 7 such as a current flowing through the first end 751 and the second end 752 or a magnetic field 755 in a magnetically interactive distance in phase with the five magnetic cores 701, 702, 703, 704 and 705, a first inductance drop measured between the first end 751 and the second end 752 of an occurrence of a first saturation of any one of the five magnetic cores 701, 702, 703, 704 and 705 will result in an abrupt current pull from a power source 777 that will be easier to trigger a second inductance drop of an occurrence of a second saturation for attracting more current from the power source 777 which is more capable of further making a next saturation happen. Each saturation produces a current pull from the power source 777 and multiple saturations one by one in a row produce multiple current pulls in a row from the power source 777. This is like a chain of reactions and multiple inductance droppings and impedance droppings in a row result in forming a bigger-and-bigger and more continous current pulled from the power source 777.

A magnetic core or a magnetic conductor which is never saturated by a magnetization is called “unsaturable magnetic core” or “unsaturable magnetic conductor” by the magnetization in the present invention. A magnetic core or a magnetic conductor which can be saturated by a magnetization is called “saturable magnetic core” or “saturable magnetic conductor” by the magnetization in the present invention.

If at least one magnetic core of the five magnetic cores 701, 702, 703, 704 and 705 of the five on-core inductors of FIG. 7 is an unsaturable magnetic core by a magnetization, then the five on-core inductors has a non-zero inductance measured between the first end 751 and the second end 752 by the magnetization. If all the magnetic cores of the five magnetic cores 701, 702, 703, 704 and 705 of the five on-core inductors of FIG. 7 are saturable magnetic cores by a magnetization, then the five on-core inductors has a zero inductance measured between the first end 751 and the second end 752 by the magnetization.

Some important concepts can be revealed by an equation

$$V = {L}_{eq} \frac{d i}{d t}$$

even though the equation has been simplified on some assumptions. V can be the voltage across the first end 751 and the second end 752 of the five on-core inductors, L_{eq} can be the equivalent inductance measured between the first end 751 and the second end 752 of the five on-core inductors, and i can be the current flowing through the first end 751 and the second end 752 of the five on-core inductors. For example, if a magnetization such as a current flowing through the the first end 751 and the second end 752 of the five on-core inductors or a magnetic field 755 in a magnetically interactive distance in phase with the five magnetic cores 701, 702, 703, 704 and 705 of FIG. 7 reduces its inductance from L_{eq} to a “non-zero”

$$\frac{{L}_{eq}}{a}$$

or a>1, then the current increases from

$$\frac{d i}{d t} to a \frac{d i}{d t}$$

as shown by

$$\begin{matrix}V = {L}_{eq} \frac{d i}{d t} \\ = ( \frac{{L}_{eq}}{a} ) ( a \frac{d i}{d t} )\end{matrix}$$

$$\frac{{L}_{eq}}{a}$$

which means that inductance L_{eq} reduced to leads to obtain a current increase

$$a \frac{d i}{d t} ,$$

which is a times of

$$\frac{d i}{d t} .$$

Assuming current starts from zero to a value i. The energy temporarily stored in the on-core inductors by the magnetization can be described by equation

$$E = \frac{1}{2} {Li}^{2}$$

Although the equation

$$E = \frac{1}{2} {Li}^{2}$$

has been simplified on some assumptions, it still can be used to build some important concepts.

An energy E₁ temporarily stored in the on-core inductors of FIG. 7 by the magnetization before the saturation can be expressed by

$${E}_{1} = \frac{1}{2} {L}_{1} {i}_{1}^{2}$$

of which L₁ and i₁ are respectively the inductance of the on-core coils measured between the first end 751 and the second end 752 and current flowing through the first end 751 and the second end 752 of the five on-core inductors of FIG. 7 before saturation. After saturations, inductance drops from L_{eq} to a “non-zero”

$$\frac{{L}_{eq}}{a} ,$$

then an energy E₂ temporarily stored in the on-core inductors of FIG. 7 by the magnetization after the saturation can be expressed by

$${E}_{2} = \frac{1}{2} \frac{{L}_{1}}{a} {( {ai}_{1} )}^{2}$$

$$or$$

$$\begin{matrix}{E}_{2} = \frac{1}{2} \frac{{L}_{1}}{a} {( {ai}_{1} )}^{2} \\ = \frac{1}{2} {aL}_{1} {i}_{1}^{2} \\ = {aE}_{1}\end{matrix}$$

after some calculations has revealed that E₂₇ the energy temporarily stored in the on-core inductors of FIG. 7 by the magnetization after the saturation, is a times of E₁, the energy temporarily stored in the on-core inductors of FIG. 7 before the saturation, in other words, the drop of the inductance from L₁ to

$$\frac{{L}_{1}}{a}$$

results in increasing tne current pulled from the power source 777 and increasing the magnetic energy E₂ temporarily stored in the on-core inductors, which is a times of the magnetic energy E₁ temporarily stored in the on-core inductors before the saturation.

If a magnetization such as a current flowing through the the first end 751 and the second end 752 of the five on-core inductors or a magnetic field 755 in a magnetically interactive distance in phase with the five magnetic cores 701, 702, 703, 704 and 705 of FIG. 7 reduces its inductance from L_{eq} to zero, then the five on-core inductors can be viewed as disappeared as a short circuit such that the electrical energy from the current can't be converted into a magnetic energy storing in the five on-core inductors.

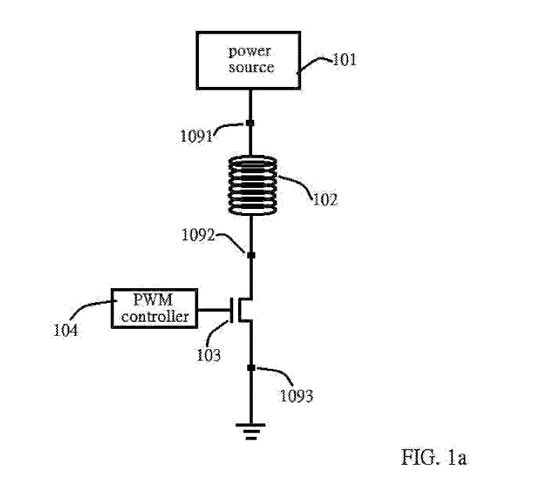

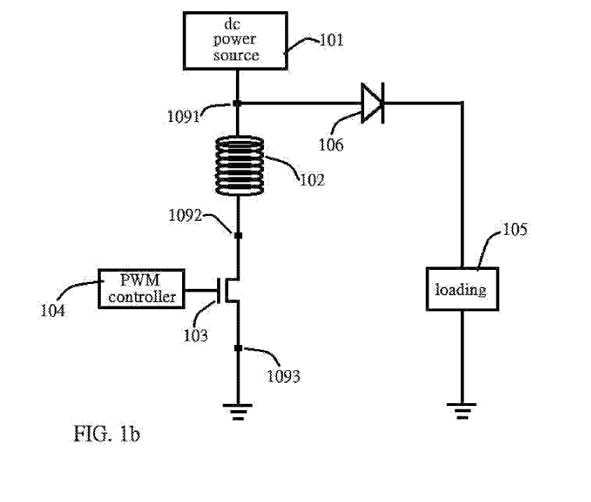

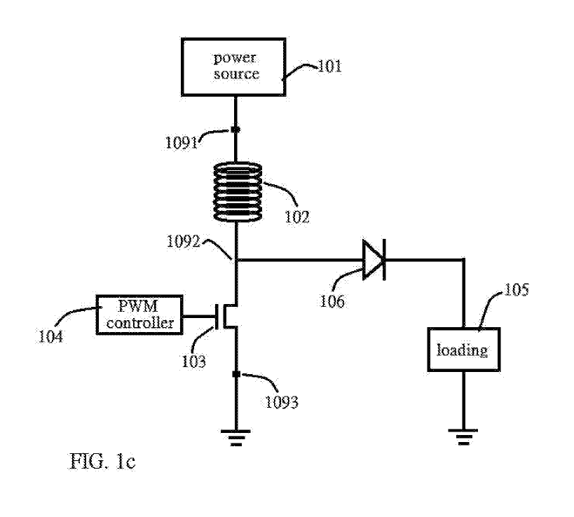

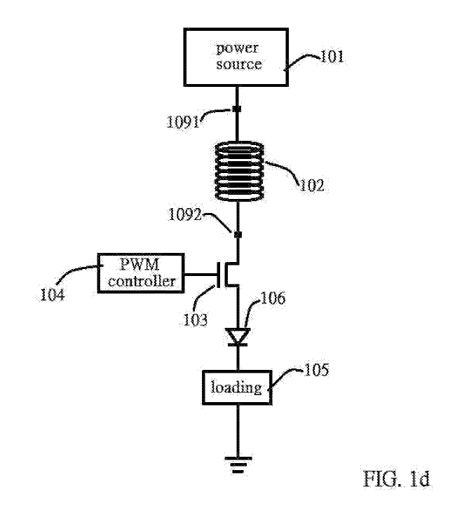

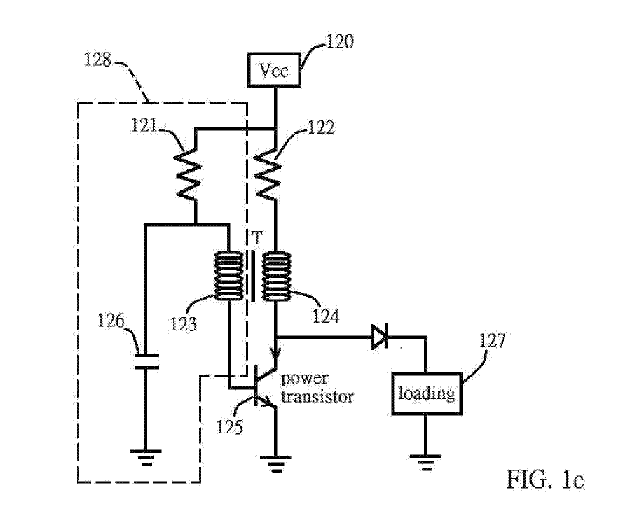

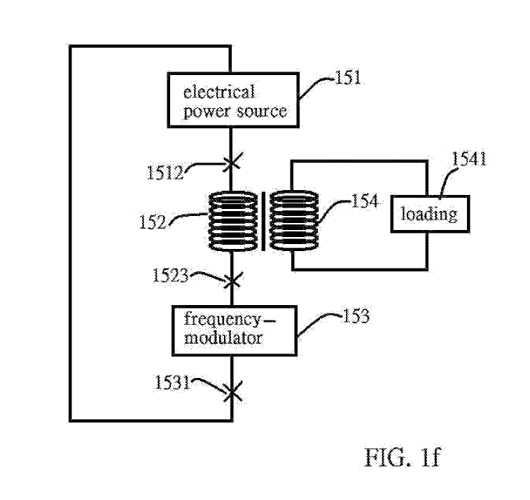

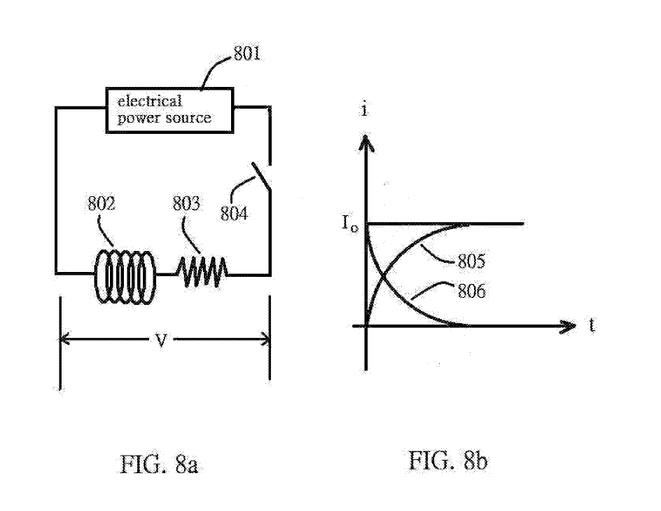

Obviously, the inductance drop of the five on-core inductors of FIG. 7 by a magnetization can attract more electrical energy from the power source 777 into a magnetic energy temporarily stored in the five on-core inductors. An inductive circuit or a switching circuit of FIG. 1f is also discussed for the help of the revelation . An inductive circuit shown in FIG. 8a has shown a power source 801, an inductor 802, a resistance 803 of the inductor 802 and a switch 804 electrically connected in series with each other and its a known typical current-time characteristic is shown in FIG. 8b.

When the switch 804 is switched “on” to a closed position, a current from the power source 801 starts to magnetize the inductor 802 and the current from the power source 801 flowing through the inductor 802 starts from zero until a maxmum is reached at a time interval t₁ as shown by a rising curve 805 in FIG. 8b. When the switch 804 is switched “off” to an open position, the current from the power source 801 stops and a magnetic energy temporarily stored in the inductor 802 is released in a current decaying from the maximum to zero at a time interval t₂.

The rising curve 805 and the decaying curve 806 are respectively governed and explained by known equations

$$i = \frac{V}{r} ( 1 - {e}^{\frac{- rt}{L}} )$$

and equation

$$i = {I}_{0} e \frac{- rt}{L}$$

respectively.

Looking at the equations

$$i = \frac{V}{r} ( 1 - {e}^{\frac{- rt}{L}} )$$

$$and$$

$$i = {I}_{0} e \frac{- rt}{L}$$

if L is constant, then the term

$$\frac{- rt}{L}$$

is dominated by a time variable t such that it takes time interval t₁ for the rising curve 805 rising from zero to the maximum and it takes time interval t₂ for the decaying curve 806 decaying from the maximum to zero. If L drops to a small non-zero value, then L can be more than the time variable t to dominate the term

$$\frac{- rt}{L} .$$

It can be helped by the analysis of the equation

$$\begin{matrix}V = L \frac{d i}{d t} \\ = ( \frac{L}{a} ) ( a \frac{d i}{d t} ) \\ = ( \frac{L}{a} ) ( \frac{d i}{\frac{d t}{a}} )\end{matrix}$$

which expresses that if inductance drops from L to a “non-zero”

$$\frac{L}{a}$$

for a>1, then current reaches the maximum at a time interval

$$\frac{1}{a} d t ,$$

which is

$$\frac{1}{a}$$

of time dt to ream tne maximum. According to the above analysis, current rise of equation

$$i = \frac{V}{r} ( 1 - {e}^{\frac{- rt}{L}} )$$

and current decay of equation

$$i = {I}_{0} e \frac{- rt}{L}$$

can be respectively more followed by the variations of L than the time variable i and respectively more quickly oscillate upward to reach the maximum and downward from the maximum to drop to zero.

Quick current rise by a magnetization and quick current decay with the magnetization removed of the inductive circuit of FIG. 8a imply the higher operation frequency capabality of the inductor 802.

Please note that the inductive circuit of FIG. 8a is the switching circuit of FIG. 1f of which the frequency modulator 153 is the switch 804 of FIG. 8a. The embodiment of the inductive circuit of FIG. 8a has proved the higher operation frequency capability of the switching circuit of FIG. 1f by dropping the inductance of the inductor. And, accordingly, the inductance drop of the five on-core inductors of FIG. 7 by a magnetization has also characterized higher operation frequency capability.

If more and more on-core inductors are electrically connected in series with each other and the magnetic cores of the on-core inductors have different saturation levels from each other for producing saturations in a row by a magnetization, then more inductance variations of the on-core inductors by the magnetization can be obtained.

For the purpose of convenience, if a plurality of on-core inductors are electrically connected in series with each other and the magnetic cores of the plurality of on-core inductors have different saturation levels from each other aiming for producing saturations one by one in a row by a magnetization, then the plurality of on-core inductors is called “serial on-core-inductor assembly” in the present invention.

The “serial on-core-inductor assembly” still allows a plurality of magnetic cores to have a same saturation level, and if it is the case, then the plurality of magnetic cores having the same saturation level to produce saturations at the same time by a magnetization can be treated as one magnetic core to conform to the definition of the “serial on-core-inductor assembly”.

The number of coil turns around each magnetic core of an “serial on-core-inductor assembly” may be different from each other. The magnetic cores of an “serial on-core-inductor assembly” may be different from each other in material, structure, shape and size. The coils around the magnetic cores of an “serial on-core-inductor assembly” may be different from each other in material, conductivity, and diameter.

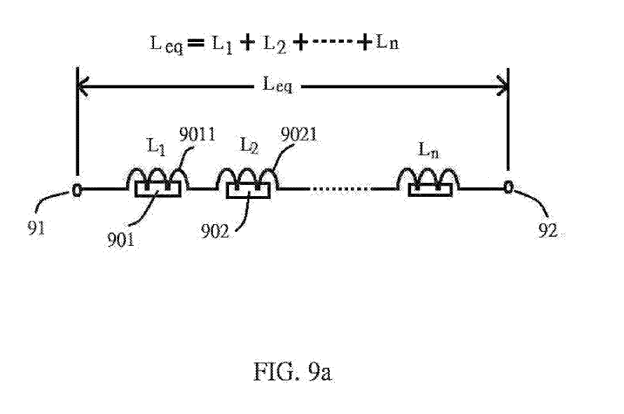

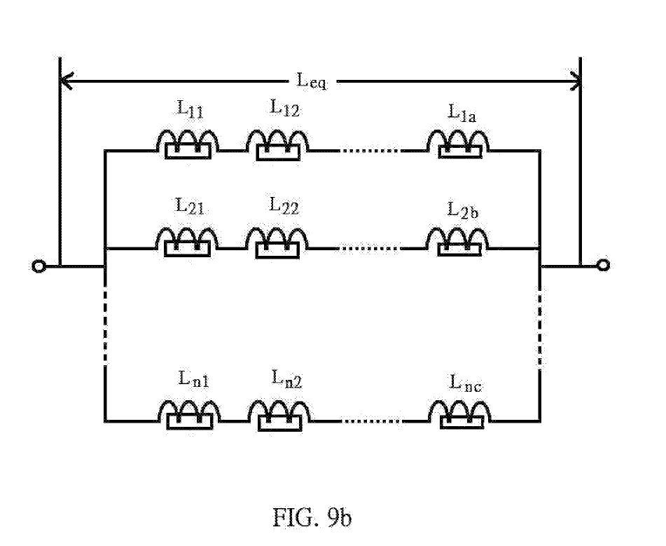

FIG. 9a has shown a “serial on-core-inductor assembly” in general form which is formed by n on-core inductors electrically connected in series with each other and a first end 91 and a second end 92 of the “serial on-core-inductor assembly” are formed by the connections of the n on-core inductors. The n on-core inductors respectively have an inductance L₁, L₂ . . . to Lₙ.

FIG. 9a has shown a first on-core inductor formed by a first coil 9011 winding around a first magnetic core 901, a second on-core inductor formed by a second coil 9021 winding around a second magnetic coil 902, and so on. L_{eq} is the inductance of the “serial on-core-inductor assembly” measured between the first end 91 and the second end 92 as the summation of L₁, L₂ . . . to Lₙ.

If the number of on-core inductors of a “serial on-core-inductor assembly” becomes larger and larger, then more and more variations of the inductances of the “serial on-core-inductor assembly” by a magnetization can be obtained. More complicated variations of the inductances of a “serial on-core-inductor assembly” provide better impedance-matching flexibility.

If a “serial on-core-inductor assembly” has at least an unsaturable magnetic core by a magnetization, then the “serial on-core-inductor assembly” has a non-zero inductance by the magnetization. A “serial on-core-inductor assembly” having a non-zero inductance by a magnetization is called “non-zero-inductance serial on-core-inductor assembly” by the magnetization in the present invention.

If a “serial on-core-inductor assembly” has all saturable magnetic cores by a magnetization, then the “serial on-core-inductor assembly” has a zero inductance by the magnetization. For the purpose of convenience, a “serial on-core-coil assembly” having a zero inductance by a magnetization is called “zero-inductance serial on-core-inductor assembly” by the magnetization in the present invention.

A “parallel on-core-inductor assembly” is formed by a plurality of “serial on-core-inductor assemblies” electrically connected in parallel with each other and the plurality of serial on-core-inductor assemblies can have different numbers of on-core inductors from each other. FIG. 9b has shown a “parallel on-core-inductor assembly” formed by n “serial on-core-inductor assemblies” electrically connected in parallel with each other. Shown in FIG. 9b, please note that n “serial on-core-inductor assemblies” may have different numbers of on-core inductors as indicated by a, b and c respectively appeared in the different “serial on-core-inductor assemblies”.

Please note that if a “parallel on-core-inductor assembly” has a “zero-inductance serial on-core-inductor assembly”, then the inductance L_{eq} of the “parallel on-core-inductor assembly” will become zero as proved by equation

$${L}_{eq} = \frac{{L}_{1} {L}_{2} {L}_{3} {L}_{4} … {L}_{n}}{( X )}$$

of which (X) expresses its long denominator for the purpose of simplification. Equation

$${L}_{eq} = \frac{{L}_{1} {L}_{2} {L}_{3} {L}_{4} … {L}_{n}}{( X )}$$

expresses any one of the L₁L₂L₃L₄ . . . Lₙ becomes zero to lead to L_{eq}=0.

If a “parallel on-core-inductor assembly” has a zero inductance by a magnetization, then the “parallel on-core-inductor assembly” is called “zero-inductance parallel on-core-inductor assembly” by the magnetization. If a “zero-inductance parallel on-core-inductor assembly” by a magnetization needs to be avoided, then the “parallel on-core-inductor assembly” should be formed by a plurality of “non-zero-inductance serial on-core-inductor assemblies” electrically connected in parallel with each other.

If a “parallel on-core-inductor assembly” has a non-zero inductance by a magnetization, then the “parallel on-core-inductor assembly” is called “non-zero-inductance parallel on-core-inductor assembly” by the magnetization.

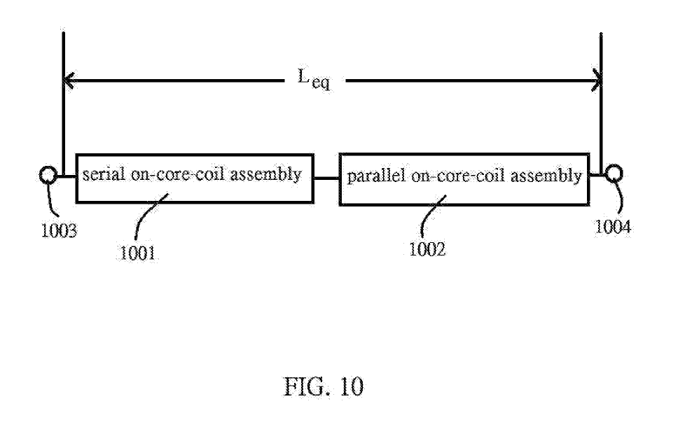

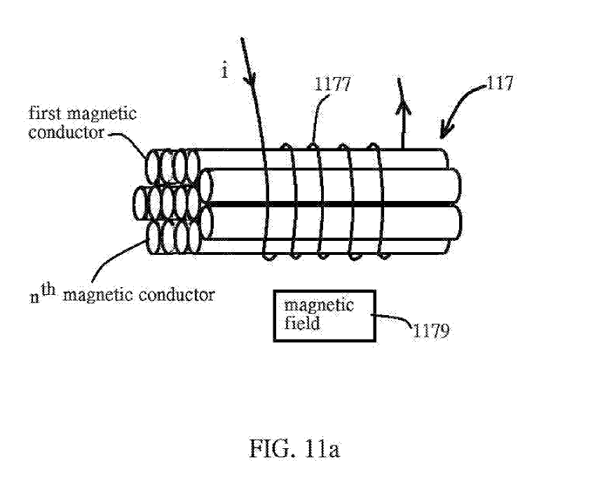

A “parallel-serial on-core-inductor assembly” comprises a “serial on-core-inductor assembly” and a “parallel on-core-inductor assembly” electrically connected in series with each other. FIG. 10 has shown an embodiment of a “parallel-serial on-core-inductor assembly” having a “serial on-core-inductor assembly” 1001 and a “parallel on-core-inductor assembly” 1002 electrically connected in series. Please note that a first end 1003 and a second end 1004 are formed by the connection of the “serial on-core-inductor assembly” 1001 and the “parallel on-core-inductor assembly” 1002.

If a “parallel-serial on-core-inductor assembly” has a non-zero inductance by a magnetization, then the “parallel-serial on-core-inductor assembly” is called “non-zero-inductance parallel-serial on-core-inductor assembly” by the magnetization.

If a “parallel-serial on-core-inductor assembly” has zero inductance by a magnetization, then the “parallel-serial on-core-inductor assembly” is called “zero-inductance parallel-serial on-core-inductor assembly” by the magnetization.

A “serial on-core-inductor assembly”, a “parallel on-core-inductor assembly” or a “parallel-serial on-core-inductor assembly” respectively defined above can be viewed as an inductor with variable inductances or a variable inductor by a magnetization.

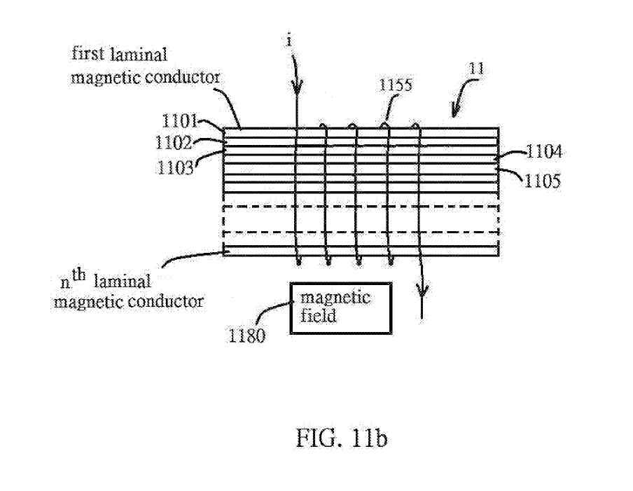

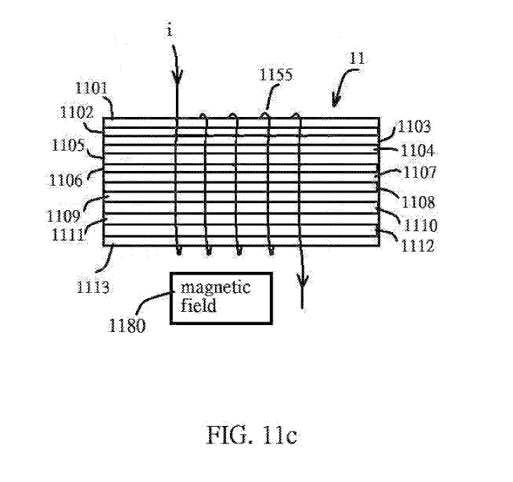

Too many conductive coils winding on the magnetic cores of a “serial on-core-inductor assembly”, a “parallel on-core-inductor assembly”, or a “parallel-serial on-core-inductor assembly” makes it very difficult to manufacture and their total inductances will be very big to limit input current. The drawbacks can be solved by a conductive coil winding on a magnetic core formed by a plurality of magnetic conductors having different saturation levels from each other respectively as shown in FIG. 11a and 11b.

FIG. 11a has shown an embodiment of a magnetic core 117 having n magnetic conductors having different saturation levels or different B-H loop patterns from each other aimimg for producing saturations one by one in a row excited by a magnetization such as a current i flowing through a conductive coil 1177 winding around the n magnetic conductors, a neighboring magnetic field 1179 in a magnetically interactive distance in phase with at least a portion of the n magnetic conductors, or the combinations of thereof. The “n” is an integer larger than 1. For the purpose of convenience, the magnetic core 117 of FIG. 11a is called “multiple-magnetic-conductor magnetic core” in the present invention. The magnetic conductors of the multiple-magnetic-conductor magnetic core of FIG. 11a may be different from each other in shape, material, size and conductivity, for example, they can be conductive or non-conductive.

The “multiple-magnetic-conductor magnetic core” still allows a plurality of magnetic conductors to have a same saturation level, and if it is the case, then the plurality of magnetic conductors having the same saturation level to produce saturations at the same time by a magnetization can be treated as one magnetic conductor to conform to the definition of the “multiple-magnetic-conductor magnetic core”.

The conductive coil 1177 winding around the n magnetic conductors of FIG. 11a forms an inductor with variable inductances or a variable inductor excited by a magnetization such as a current i flowing through the conductive coil 1177, the neighboring magnetic field 1179 in a magnetically interactive distance in phase with at least a portion of the n magnetic conductors, or the combinations of thereof. For the purpose of convenience, the variable inductor is called “multiple-magnetic-conductor inductor” in the present invention. Variable inductances of the conductive coil 1177 can be obtained by a plurality of saturations of the n magnetic conductors in a row by the magnetization.

If a “multiple-magnetic-conductor inductor” has a non-zero inductance by a magnetization, then the “multiple-magnetic-conductor inductor” is called “non-zero-inductance multiple-magnetic-conductor inductor” by the magnetization. If a “multiple-magnetic-conductor inductor” has a zero inductance by a magnetization, then the “multiple-magnetic-conductor inductor” is called “zero-inductance multiple-magnetic-conductor inductor” by the magnetization.

Each magnetic conductor of the magnetic core 117 of FIG. 11a can be in laminal shape and n laminal magnetic conductors are piled up by laying a laminal magnetic conductor on another laminal magnetic conductor a side view of which is shown in FIG. 11b. The n laminal magnetic conductors of the magnetic core of FIG. 11b have different saturation levels or different B-H loop patterns from each other aiming for producing saturations one by one in a row excited by a magnetization such as a current i flowing through a conductive coil 1155 winding around the n laminal magnetic conductors, a neighboring magnetic field 1180 in a magnetically interactive distance in phase with at least a portion of the n laminal magnetic conductors, or the combination of thereof.

For the purpose of convenience, the magnetic core of FIG. 11b is called “multiple-laminal-magnetic-conductor magnetic core” in the present invention. The magnetic conductors of the multiple-laminal-magnetic-conductor magnetic core of FIG. 11b may be different from each other in shape, material, thickness and conductivity, for example, they can be conductive or non-conductive.

The “multiple-laminal-magnetic-conductor magnetic core” still allows a plurality of laminal magnetic conductors to have a same saturation level, and if it is the case, then the plurality of laminal magnetic conductors having the same saturation level to produce saturations at the same time by a magnetization can be treated as one laminal magnetic conductor to conform the definition of the “multiple-laminal-magnetic-conductor magnetic core”.

The conductive coil 1155 winding around the “multiple-laminal-magnetic-conductor magnetic core” of FIG. 11b forms an inductor which can be called “multiple-laminal-magnetic-conductor inductor” in the present invention. Following is the mathematic analysis describing a multiple-laminal-magnetic-conductor inductor. A known equation

$$V = ( \frac{0.4 πμ {AN}^{2}}{{10}^{8} l} ) \frac{d i}{d t}$$

describes a specific inductor formed by a conductive coil winding around a specific magnetic core. N is the number of coil turns around the magnetic core, A is the cross-section area of the magnetic core, l is the mean length of one coil turn around the magnetic core, and

$$μ = \frac{B}{H}$$

is the magnetic permeability of the magnetic core such that

$$\begin{matrix}V = ( \frac{0.4 πμ {AN}^{2}}{{10}^{8} l} ) \frac{d i}{d t} \\ = ( \frac{0.4 π \frac{B}{H} {AN}^{2}}{{10}^{8} l} ) \frac{d i}{d t}\end{matrix}$$

Once the magnetic core and the number of coil turns are decided, the term

$$( \frac{0.4 π {AN}^{2}}{{10}^{8} l} )$$

is decided.

Although equation

$$V = ( \frac{0.4 πμ {AN}^{2}}{{10}^{8} l} ) \frac{d i}{d t}$$

is obtained for a specific magnetic core, it still can be used to build some important concepts. Comparing

$$V = ( \frac{0.4 πμ {AN}^{2}}{{10}^{8} l} ) \frac{d i}{d t}$$

with known

$$V = L \frac{d i}{d t} , ( \frac{0.4 πμ {AN}^{2}}{{10}^{8} l} )$$

describes its inductance term and once the magnetic core and the number of coil turns are decided, the term

$$( \frac{0.4 π {AN}^{2}}{{10}^{8} l} )$$

is decided such that the magnetic permeability

$$μ = \frac{B}{H}$$

is proportional to it inductance L.

Assuming the magnetic core has n laminal magnetic conductors as shown in FIG. 11b and letting each of the n laminal magnetic conductors of FIG. 11b has a (B₁, H₁), (B₂,H₂) . . . (Bₙ,Hₙ). For example, a first laminal magnetic conductor 1101 has a first flux density B₁ by a first magnetization H₁ and a second laminal magnetic conductor 1102 next to the first laminal magnetic conductor 1101 has a second flux density B₂ by a second magnetization H₂ and so on.

Assuming no magnetic crosstalk exists among adjacent laminal magnetic conductors and assuming the magnetization such as a current flow through the conductive coil 1155 is same to each laminal magnetic conductor for the purpose of simplification, which means H=H₁=H₂=H₃= . . . =Hₙ.

Equation

$$\begin{matrix}V = ( \frac{0.4 π \frac{B}{H} {AN}^{2}}{{10}^{8} l} ) \frac{d i}{d t} \\ = ( \frac{0.4 π {AN}^{2}}{{10}^{8} l} ) ( \frac{B}{H} ) \frac{d i}{d t} \\ = ( \frac{0.4 π {AN}^{2}}{{10}^{8} l} ) ( \frac{{B}_{1} + {B}_{2} + … + {B}_{n}}{H} ) \frac{d i}{d t} \\ = L \frac{d i}{d t}\end{matrix}$$

has revealed that the saturation of each magnetic conductor by the magnetization corresponds to an inductance drop of the conductive coil 1155 winding around the n laminal magnetic conductors. Multiple saturations of the n laminal magnetic conductors in a row result in the multiple inductance droppings in a row.

In reality, the behavior of the embodiment of FIG. 11b is a lot more complicated, for example, temperature differences among the n laminal magnetic conductors, heat dissipation condition differences among the n laminal magnetic conductors, and magnetic crosstalks among the plurality of laminal magnetic conductors may all get involved in.

The conductive coil 1155 winding around the “multiple-laminal-magnetic-conductor magnetic core” of FIG. 11b forms an inductor with variable inductances excited by a magnetization such as a current i flowing through the conductive coil 1155, the neighboring magnetic field 1180 in a magnetically interactive distance in phase with at least a portion of the n laminal magnetic conductors, or the combination of thereof. For the purpose of convenience, the variable inductor is called “multiple-laminal-magnetic-conductor inductor” in the present invention. Variable inductances of the conductive coil 1155 can be obtained by the saturations of the n laminal magnetic conductors one by one in a row by the magnetization.

If a “multiple-magnetic-conductor inductor” or a “multiple-laminal-magnetic-conductor inductor” has at least an unsaturable magnetic conductor by a magnetization, then the “multiple-magnetic-conductor inductor” or the “multiple-laminal-magnetic-conductor inductor” has a non-zero inductance by the magnetization. If a “multiple-magnetic-conductor inductor” or a “multiple-laminal-magnetic-conductor inductor” has all saturable magnetic conductors by a magnetization, then the “multiple-magnetic-conductor inductor” or the “multiple-laminal-magnetic-conductor inductor” has a zero inductance by the magnetization.

If a “multiple-laminal-magnetic-conductor inductor” has a non-zero inductance by a magnetization, then the “multiple-laminal-magnetic-conductor inductor” is called “non-zero-inductance multiple-laminal-magnetic-conductor inductor” by the magnetization. If a “multiple-laminal-magnetic-conductor inductor” has a zero inductance by a magnetization, then the “multiple-laminal-magnetic-conductor inductor” is called “zero-inductance multiple-laminal-magnetic-conductor inductor” by the magnetization.

If two adjacent magnetic conductors of the multiple-magnetic-conductor magnetic core of FIG. 11a and the multiple-laminal-magnetic-conductor magnetic core of FIG. 11b are conductive, then an electrical isolator can be disposed between the two adjacent conductive magnetic conductors for electrically isolating them against forming into a bigger size conductor advantaging for the development of so called “Eddy current”. For example, by using FIG. 11b, if assuming a third lamina 1103 and a fifth lamina 1105 are conductive magnetic conductors, then a fourth lamina 1104 can be an electrical isolator for electrically isolating them.

If each lamina of a multiple-laminal-magnetic-conductor magnetic core has a thickness smaller than its associated penetration depth of skin effect, then the “Eddy current” problem can be also reduced because “Eddy current” has less space to stay. Seen at different materials, a penetration depth of skin effect of different materials range roughly between 14˜28 mils according to some researches. Thin laminal magnetic conductor and electrical isolator can be respectively formed by spraying or coating their associated materials on another lamina.

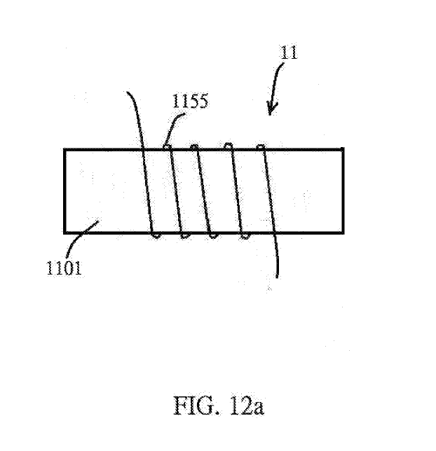

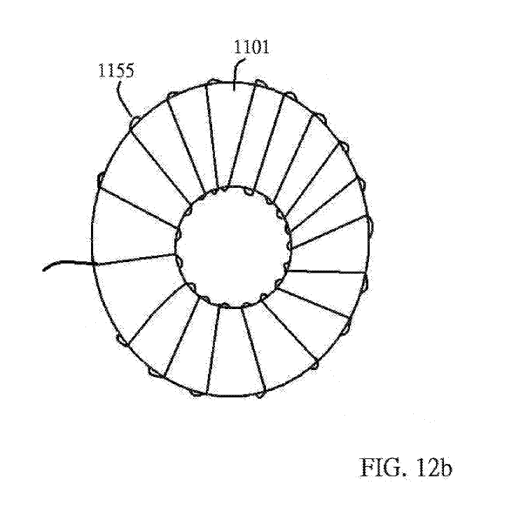

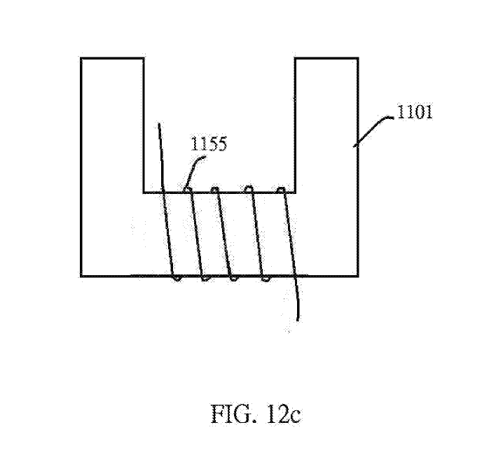

Non-conductive laminal magnetic conductor of a multiple-laminal-magnetic-conductor magnetic core has disadvantaged the development of “Eddy current” such that if all the laminal magnetic conductors of the multiple-laminal-magnetic-conductor magnetic core of FIG. 11b are non-conductive, then the induced so called “Eddy current” problem can be further reduced. FIG. 11b has shown the multiple-laminal-magnetic-conductor magnetic core in side view, but the shape of the multiple-laminal-magnetic-conductor magnetic core of FIG. 11b is not limited, for example, a top view of the multiple-laminal-magnetic-conductor magnetic core of FIG. 11b can be in I-shape as shown in FIG. 12a, ring-like shape shown in FIG. 12b, or U-shape shown in FIG. 12c. Please note that the ring-like multiple-laminal-magnetic-conductor magnetic core shown in FIG. 12b have advantaged a closed magnetic path for better magnetic conduction efficiency.

If at least one magnetic conductor of a multiple-laminal-magnetic-conductor magnetic core is a “saturable magnetic conductor” by a magnetization such as a current flowing through a conductive coil winding around the multiple-laminal-magnetic-conductor magnetic core or a neighboring magnetic field in a magnetically interactive distance in phase with the multiple-laminal-magnetic-conductor magnetic core, then the inductance of the conductive coil winding around the multiple-laminal-magnetic-conductor magnetic core changes to drop by the magnetization.

If at least one magnetic conductor of a multiple-laminal-magnetic-conductor magnetic core is not saturated by a magnetization such as a current flowing through a conductive coil winding around the multiple-laminal-magnetic-conductor magnetic core or a neighboring magnetic field in a magnetically interactive distance in phase with the multiple-laminal-magnetic-conductor magnetic core, then the conductive coil winding around the multiple-laminal-magnetic-conductor magnetic core will have a non-zero inductance by the magnetization.

If all the magnetic conductors of a multiple-laminal-magnetic-conductor magnetic core are saturated by a magnetization such as a current flowing through a conductive coil winding around the multiple-laminal-magnetic-conductor magnetic core or a neighboring magnetic field in a magnetically interactive distance in phase with the multiple-laminal-magnetic-conductor magnetic core, then the conductive coil winding around the multiple-laminal-magnetic-conductor magnetic core will have zero inductance by the magnetization.

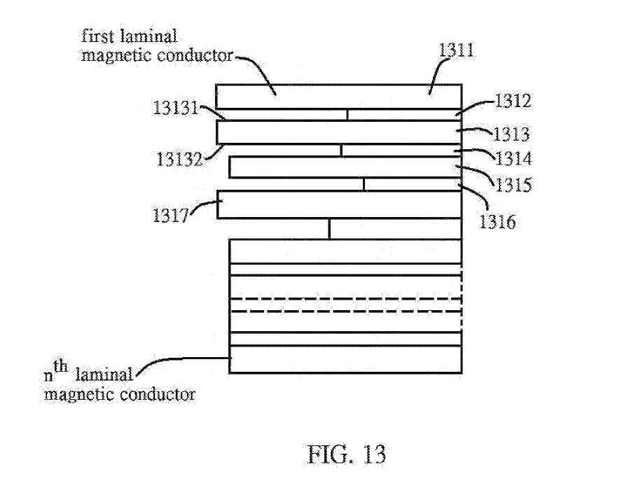

A magnetic conductor in saturation produces heat so that the heat dissipation may be considered. FIG. 13 has shown a multiple-laminal-magnetic-conductor magnetic core having n laminal magnetic conductors in side view piled up by laying a laminal magnetic conductor on another laminal magnetic conductor. The n laminal magnetic conductors may be different from each other in shape, thickness and material. At least a portion of a side of a laminal magnetic conductor facing adjacent laminal magnetic conductor has an area for contacting cooling matter such as air or cooling fluid for better heat dissipation capability. For example, a laminal magnetic conductor 1313 shown in FIG. 13 has two sides 13131, 13132 respectively facing an adjacent laminal magnetic conductor 1312 and laminal magnetic conductor 1314. At least a portion of each of the two sides 13131 and 13132 are exposed for contacting cooling matter such as air or cooling fluid. An electrical isolator can be disposed between two adjacent conductive laminal magnetic conductors, for example by using FIG. 13, if a laminal magnetic conductor 1315 and a laminal magnetic conductor 1317 are conductive, then a laminal magnetic conductor 1316 can be an electrical isolator to electrically isolate the laminal magnetic conductor 1315 and the laminal magnetic conductor 1317 against forming a bigger conductive body advantaging the development of “Eddy current”.

A magnetic conductor in saturation produces heat so that the easiest saturable magnetic conductor or a magnetic conductor with the lowest saturation level can be disposed at a best heat dissipation location, for example, by using a 13-lamina multiple-laminal-magnetic-conductor magnetic core of FIG. 11c, a top 1101 or a bottom lamina 1113 of the multiple-laminal-magnetic-conductor magnetic core of FIG. 11c has more area for contacting cooling matter such as air or cooling fluid. A magnetic conductor with the second lowest saturation level can be disposed at a lamina next to the top lamina 1101 or the bottom lamina 1113 and so on the logic such that an unsaturable magnetic conductor or a magnetic conductor with the highest saturation level can be disposed at a worst heat dissipation location such as a lamina at or around the middle of multiple-laminal-magnetic-conductor magnetic core, by using the multiple-laminal-magnetic-conductor magnetic core of FIG. 11c, the lamina 1107 or around lamina 105 or lamina 106.

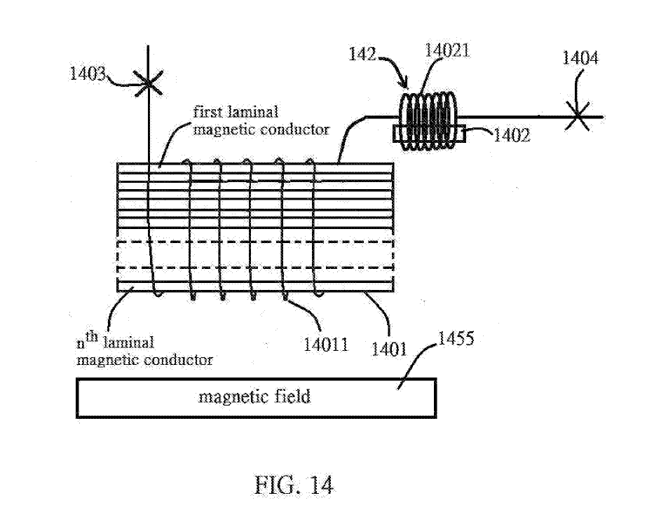

FIG. 14 has shown an embodiment of a “non-zero-inductance serial on-core-inductor assembly” having two on-core inductors electrically connected in series. One of the two on-core inductors is a “zero-inductance multiple-laminal-magnetic-conductor inductor” formed by a first conductive coil 14011 winding around a “multiple-laminal-magnetic-conductor magnetic core 1401” of FIG. 11b having all saturable laminal magnetic conductors and the other on-core inductor is formed by a second conductive coil 14021 winding around an unsaturable magnetic core 1402 by a magnetization such as a current flowing through the first conductive coil 14011 and the second conductive coil 14021 or a neighboring magnetic field 1455 in a magnetically interactive distance in phase with “multiple-laminal-magnetic-conductor magnetic core 1401” and the magnetic core 1402. A first end 1403 and a second end 1404 are formed by the connection of the first conductive coil 14011 and the second conductive coil 14021. A non-zero inductance measured between the first end 1403 and the second end 1404 can be obtained by the magnetization.

A “serial on-core-inductor assembly”, a “parallel on-core-inductor assembly”, a “parallel-serial on-core-inductor assembly”, a “multiple-magnetic-conductor inductor” or a “multiple-laminal-magnetic-conductor inductor” can be employed to remedy the drawbacks of the switching circuit of FIG. 1f and some circuits constructed by the switching circuit of FIG. 1f such as the second boost circuit of FIG. 1c, the buck circuit of FIG. 1d, and of the blocking oscillator of FIG. 1e.

A “multiple-magnetic-conductor inductor” or a “multiple-laminal-magnetic-conductor inductor” can be employed to remedy the drawbacks of traditional transformer core, electric motor core, and electric generator core revealed in the background information section.

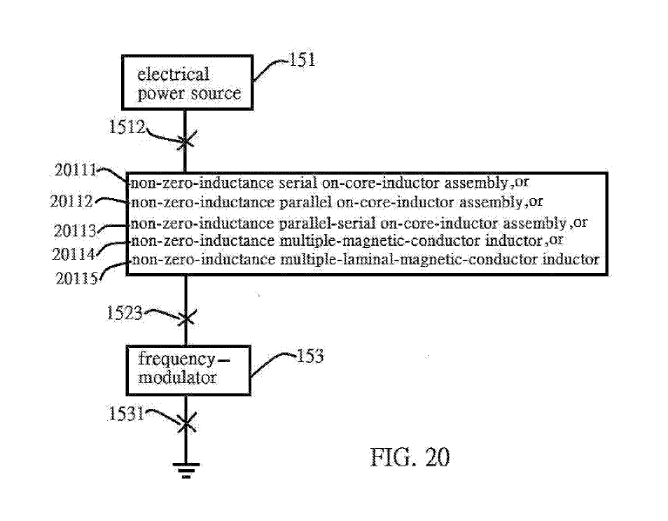

For example, using the switching circuit of FIG. 1f, FIG. 20 has shown the switching circuit of FIG. 1f except the inductor 152 of the switching circuit of FIG. 1f is substituted by a “non-zero-inductance serial on-core-inductor assembly” 20111, a “non-zero-inductance parallel on-core-inductor assembly” 20112, a “non-zero-inductance parallel-serial on-core-inductor assembly” 20113, a “non-zero-inductance multiple-magnetic-conductor inductor” 20114 or a “non-zero-inductance multiple-laminal-magnetic-conductor inductor” 20115. A non-zero inductance promises that a safe impedance between the power source 151 and the ground of FIG. 20 is guaranteed.

The inductor 102 of the first boost circuit of FIG. 1b, the inductor 102 of the second boost circuit of FIG. 1c, the inductor 102 of the buck circuit of FIG. 1d, the inductor 124 of the blocking oscillator of FIG. 1e, and the inductor 152 of the switching circuit of FIG. 1f can be respectively substituted by a “non-zero-inductance serial on-core-inductor assembly”, a “non-zero-inductance parallel on-core-inductor assembly”, a “non-zero-inductance parallel-serial on-core-inductor assembly”, a “non-zero-inductance multiple-magnetic-conductor inductor” or a “non-zero-inductance multiple-laminal-magnetic-conductor inductor” by a magnetization to fix the drawbacks revealed in the background information section.

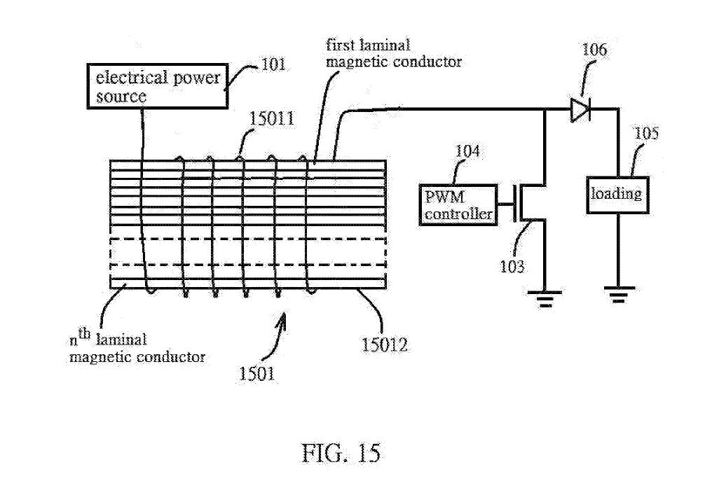

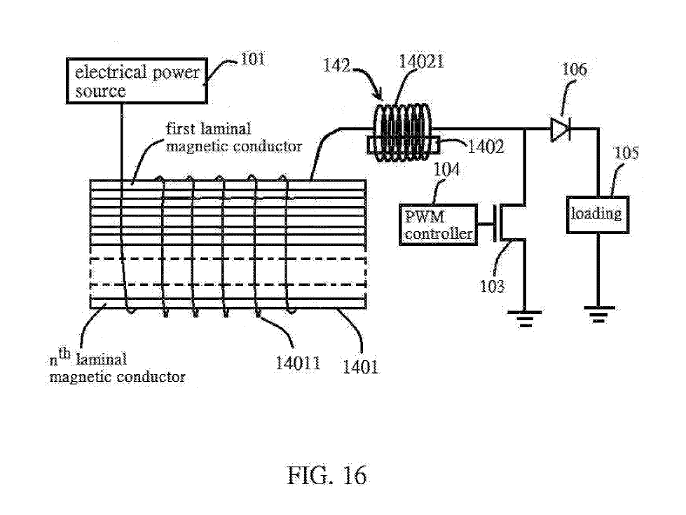

More detailed description will be shown in an embodiment of FIG. 15 by using the second boost circuit of FIG. 1c. FIG. 15 has shown the second boost circuit of FIG. 1c except the inductor 102 of FIG. 1c is subsitituted by a multiple-laminal-magnetic-conductor inductor 1501 formed by a conductive coil 15011 winding around a multiple-laminal-magnetic-conductor magnetic core 15012 revealed above in the present invention. The multiple-laminal-magnetic-conductor magnetic core 15012 has a plurality of laminal magnetic conductors having different saturation levels from each other for producing saturations one by one in a row by a magnetization.

The “multiple-laminal-magnetic-conductor magnetic core” 1501 shown in FIG. 15 still allows a plurality of laminal magnetic conductors to have a same saturation level, and if it is the case, then the plurality of laminal magnetic conductors having the same saturation level to produce saturations at the same time by a magnetization can be treated as one laminal magnetic conductor to conform to the definition of the “multiple-laminal-magnetic-conductor magnetic core”.

For the purpose of convenience, the circuit shown in FIG. 15 containing the power source 101, the multiple-laminal-magnetic-conductor inductor 1501 and the power transistor 103 electrically connecter in series with each other is called a first circuit in the present invention. Letting the multiple-laminal-magnetic-conductor inductor 1501 has an inductance L₁ before saturation.

When the power transistor 103 is switched “on” to a closed position, a magnetization such as a current from the electrical power source 101 flowing through the first circuit magnetizes the multiple-laminal-magnetic-conductor inductor 1501 to produce a plurality of saturations in a row resulting in a plurality of inductance droppings of the multiple-laminal-magnetic-conductor inductor 1501.

The plurality of inductance droppings of the multiple-laminal-magnetic-conductor inductor 1501 form multiple current pulls from the electrical power source 101 resulting in converting more electrical energy pulled from the power source 777 into a magnetic energy temporarily stored in the multiple-laminal-magnetic-conductor inductor 1501 as revealed earlier in the embodiment of FIG. 7.

When the power transistor 103 is switched “off” after the previous “on”, current stops flowing through the first circuit and the magnetic energy temporarily stored in the multiple-laminal-magnetic-conductor inductor 1501 is immediately released into current for driving the loading 105.

Current stops flowing through the first circuit restores the dropped inductance of the multiple-laminal inductor 1501 back to L₁ and the current converted by the magnetic energy stored in the multiple-laminal-magnetic-conductor inductor 1501 will again saturate the multiple-laminal-magnetic-conductor inductor 1501 resulting in the multiple inductance droppings which form a bigger-and-bigger output current for driving the loading 105 as revealed earlier in the embodiment of FIG. 7.

The multiple-laminal-magnetic-conductor inductor 1501 has at least one unsaturable magnetic conductor by a magnetization to avoid having zero inductance by the magnetization for four reasons: (1) when the power transistor 103 is on and assuming the resistance of the power transistor 103 with “on” state is very small to be ignored, the current flowing through the first circuit can be limited by a “significant” “non-zero” inductance against short circuit between the electrical power source 101 and the ground, (2) the short circuit occuring between the electrical power source 101 and the ground can very possibly destroy the power transistor 103, (3) a non-zero inductance drop promises more electrical energy from the electrical power source 101 converted into the magnetic energy storing in the multiple-laminal-magnetic-conductor inductor 1501 as revealed earlier in the embodiment of FIGS. 7, and (4) higher operation frequency capability of the boost circuit of FIG. 15 is obtained as revealed by the embodiment of FIG. 8a, 8b.

In other words, if the multiple-laminal-magnetic-conductor inductor 1501 has all saturable magnetic conductors by a magnetization to have zero inductance by the magnetization, then a short circuit will be formed between the electrical power source 101 and the ground to very possibly destroy the power transistor 103 and the magnetic energy stored in the multiple-laminal-magnetic-conductor inductor 1501 converted by the electrical energy from the electrical power source 101 will be smaller than that of a non-zero-inductance multiple-laminal-magnetic-conductor inductor by the magnetization.

Because if all the magnetic conductors of the multiple-laminal-magnetic-conductor inductor 1501 are all saturated by the magnetization, it means its inductance becomes zero, then the magnetic energy converted by the current after the saturations of all the magnetic conductors has no place to go instead it will consume in the form of heat.

The current will grow bigger and bigger pulled from the electrical power source 101 by the occurences of the saturations. Equation E=½Li² describes converting current i into a magnetic energy E stored in an inductor having a non-zero L. The stored magnetic energy E is proportional to current i of power 2 such that the final of a growing-bigger current is the most important because it can convert into the biggest magnetic energy.

For a non-zero-inductance multiple-laminal-magnetic-conductor inductor by a magnetization, the biggest magnetic energy converted by the final of a growing-bigger current can still be stored into the inductor by the magnetization, but for a zero-inductance multiple-laminal-magnetic-conductor inductor by a magnetization, the biggest magnetic energy converted by the final of a growing-bigger current by the magnetization will consume into heat.

The “significant” in “a significant non-zero inductance” means that a safe impedance between the power source 101 and the ground of the first circuit is guaranteed.

The electrical power source 101 is not limited, for example, it can be a DC power source, a solarcell or a battery. The loading 105 is not limited, for example, it can be a resistant loading, a capacitive loading or an inductive loading.

The switching circuit of FIG. 20 have shown some merits through the embodiment of the boost circuit of FIG. 15: (1) more electrical energy from the electrical power source 151 can be converted into a magnetic energy temporarily stored in the multiple-laminal-magnetic-conductor inductor 20115, (2) an electrical energy from the electrical power source 151 can be more quickly converted into a magnetic energy temporarily stored in the multiple-laminal-magnetic-conductor inductor 20115 and the magnetic energy temporarily stored in the multiple-laminal-magnetic-conductor inductor 20115 can be more quickly released into a sufficient current such that the switching circuit can operate at higher frequency as revealed by the embodiment of FIGS. 8a and 8b, (3) the magnetic energy temporarily stored in the multiple-laminal-magnetic-conductor inductor 20115 can be immediately released into a bigger-and-bigger current for ratifying loading, and (4) more complicated variations of the inductance of the multiple-laminal-magnetic-conductor inductor 20115 implies better impedance-matching capability between electrical power source and the loading, especially good for an unknown power source such as solarcell or battery and an unknown loading with variable impedances.

Obviously, the embodiment of FIG. 15 and FIG. 20 has shown the performance improvement of the switching circuit of FIG. if and circuits constructed by the switching circuit such as the first boost circuit of FIG. 1b, the second boost circuit of FIG. 1c, the buck circuit of FIG. 1d or the blocking oscillator of FIG. 1e.

The magnetic conductors of the multiple-laminal-magnetic-conductor magnetic core 15012 of FIG. 15 may be different from each other in shape, material, thickness and conductivity, for example, they can be conductive or non-conductive.

If two adjacent laminal magnetic conductors of the multiple-laminal-magnetic-conductor magnetic core 15012 of FIG. 15 are conductive, then an electrical isolator can be disposed between the two adjacent conductive laminal magnetic conductors for electrically isolating them against forming into a bigger size conductor advantaging for the developement of so called “Eddy current”. If a lamina of the multiple-laminal-magnetic-conductor magnetic core 15012 of FIG. 15 has a thickness smaller than its associated penetration depth of skin effect, then the “Eddy current” problem can be also reduced because “Eddy current” has less space to stay. Thin laminal magnetic conductor and electrical isolator can be respectively formed by spraying or coating their associated materials on another lamina.

If all the laminal magnetic conductors of the multiple-laminal-magnetic-conductor magnetic core 15012 of FIG. 15 are non-conductive, then it disadvantages the development of “Eddy current”.

At least a portion of a side of a laminal magnetic conductor of the multiple-laminal-magnetic-conductor inductor 1501 facing adjacent laminal magnetic conductor may have an area for contacting cooling matter such as air or cooling fluid for better heat dissipation capability as shown in the embodiment of FIG. 13.

A magnetic conductor in saturation produces heat so that the easiest saturable magnetic conductor or a magnetic conductor with the lowest saturation level of the multiple-laminal-magnetic-conductor inductor 1501 can be disposed at a best heat dissipation location. A magnetic conductor with the second lowest saturation level can be disposed at a lamina next to the top lamina or the bottom lamina and so on the logic.

FIG. 15 has shown the multiple-laminal-magnetic-conductor magnetic core 15012 in side view, but the shape of the multiple-laminal-magnetic-conductor magnetic core 15012 is not limited, for example, a top view of the multiple-laminal-magnetic-conductor magnetic core 15012 can be in I-shape as shown in FIG. 12a, ring-like shape shown in FIG. 12b, or U-shape shown in FIG. 12c. Please note that the ring-like multiple-laminal-magnetic-conductor magnetic core 15012 have advantaged a closed magnetic path for better magnetic conduction efficiency.

FIG. 16 has shown an embodiment by employing a “non-zero-inductance serial on-core-inductor assembly” of FIG. 14 into the second boost circuit of FIG. 1c.

FIG. 16 has shown the second boost circuit of FIG. 1c except the inductor 102 of FIG. 1c is subsitituted by a “non-zero-inductance serial on-core-inductor assembly” formed by a zero-inductance multiple-laminal-magnetic-conductor inductor 141 and a non-zero-inductance on-core inductor 142 by a magnetization electrically connected in series. FIG. 16 has shown the zero-inductance multiple-laminal-magnetic-conductor inductor formed by a first conductive coil 14011 winding around a saturable multiple-laminal-magnetic-conductor magnetic core 1401 and the non-zero-inductance on-core coil 142 formed by a second conductive coil 14021 winding around an unsaturable magnetic core 1402.

The drawback of the traditional transformer core revealed in the background information section can be remedied by using the multiple-laminal-magnetic-conductor magnetic core or the multiple-magnetic-conductor magnetic core.

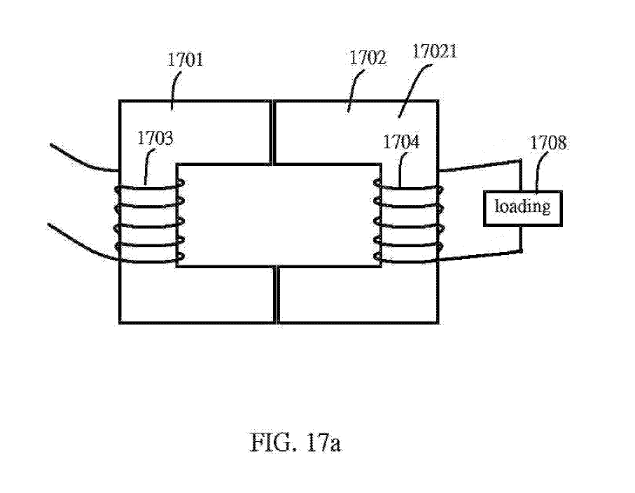

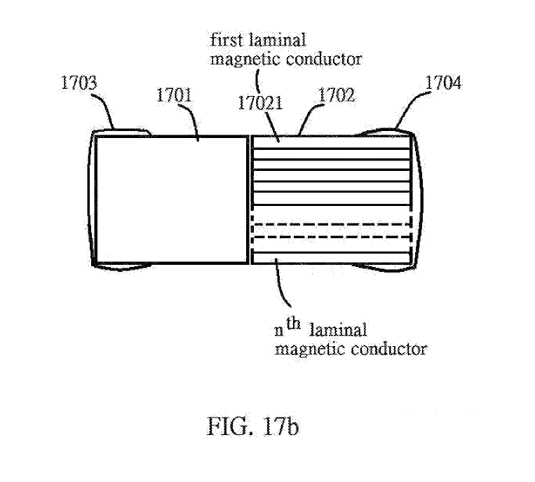

FIG. 17a has shown an embodiment of an inventive transformer core in top view formed by a primary magnetic core 1701 and a secondary multiple-laminal-magnetic-conductor magnetic core 1702 respectively wound by a primary coil 1703 and a secondary coil 1704. The secondary multiple-laminal-magnetic-conductor magnetic core 1702 in side view shown in FIG. 17b has n laminal magnetic conductors piled up by laying a laminal magnetic conductor on another laminal magnetic conductor and the n laminal magnetic conductors have different saturation levels from each other aiming to produce different saturations in a row by a magnetization. The n is an integer larger than 1.

The secondary “multiple-laminal-magnetic-conductor magnetic core” 1702 shown in FIG. 17b still allows a plurality of laminal magnetic conductors to have a same saturation level, and if it is the case, then the plurality of laminal magnetic conductors having the same saturation level to produce saturations at the same time by a magnetization can be treated as one laminal magnetic conductor.

The primary magnetic core 1701 and the secondary multiple-laminal-magnetic-conductor magnetic core 1702 are within a magnetically interactive distance with each other, for example, a closed magnetic path formed by the primary magnetic core 1701 and the secondary multiple-laminal magnetic core 1702 obtains a better magnetic conduction efficiency shown in FIG. 17a, such that a magnetic flux produced by an input current flowing through the primary coil 1703 passes through both the primary coil 1703 and the secondary coil 1704.

The n laminal magnetic conductors of the secondary multiple-laminal-magnetic-conductor magnetic core 1702 have different saturation levels from each other aiming to produce saturations in a row by a magnetization such as an output current induced on the secondary coil 1704 or a neighboring magnetic field in a magnetically interactive distance in phase with at least one of the n laminal magnetic conductors such that the inductance of the secondary coil 1704 quickly decreases and the output current are becoming larger and larger for driving the loading 1708.***********

The primary magnetic core 1701 can be a traditional magnetic core with constant inductance for limiting an input electrical power for the consideration of safety, for example, the input electrical power can be from an electrical power plant which sends huge power such that setting a limitation of such a huge input electrical power is a necessity.

The primary magnetic core 1701 is not limited in any particular structure, shape and material made of it. The inductance variations of the secondary coil 17021 provides better impedance-matching with the loading 1708.

The n laminal magnetic conductors of the multiple-laminal-magnetic-conductor magnetic core 1702 of FIGS. 17a and 17b may be different from each other in shape, material, thickness and conductivity, for example, they can be conductive or non-conductive.

If two adjacent laminal magnetic conductors of the multiple-laminal-magnetic-conductor magnetic core 1702 of FIG. 17b are conductive, then an electrical isolator can be disposed between the two adjacent conductive magnetic conductors for electrically isolating them against forming into a bigger size conductor advantaging the development of so called “Eddy current”.

If each laminal magnetic conductor of the multiple-laminal-magnetic-conductor magnetic core 1702 of FIG. 17b has a thickness smaller than its associated penetration depth of skin effect, then the “Eddy current” problem can be also reduced because “Eddy current” has less space to stay. Thin laminal magnetic conductor and electrical isolator can be respectively formed by spraying or coating their associated materials on another lamina.

If all the laminal magnetic conductors of the multiple-laminal-magnetic-conductor magnetic core 1702 of FIG. 17b are non-conductive, then it disadvantages the development of “Eddy current”.

At least a portion of a side of a laminal magnetic conductor of the multiple-laminal-magnetic-conductor magnetic core 1702 facing adjacent laminal magnetic conductor may have an area for contacting cooling matter such as air or cooling fluid for better heat dissipation capability as shown in the embodiment of FIG. 13.

A magnetic conductor in saturation produces heat so that the easiest saturable magnetic conductor or a magnetic conductor with the lowest saturation level of the multiple-laminal-magnetic-conductor magnetic core 1702 can be disposed at a best heat dissipation location. A magnetic conductor with the second lowest saturation level can be disposed at a lamina next to the top lamina or the bottom lamina and so on the logic.

The drawback of the traditional “electric motor core” and “electric generator core” revealed in the background information section can be remedied by using the multiple-laminal-magnetic-conductor magnetic core.

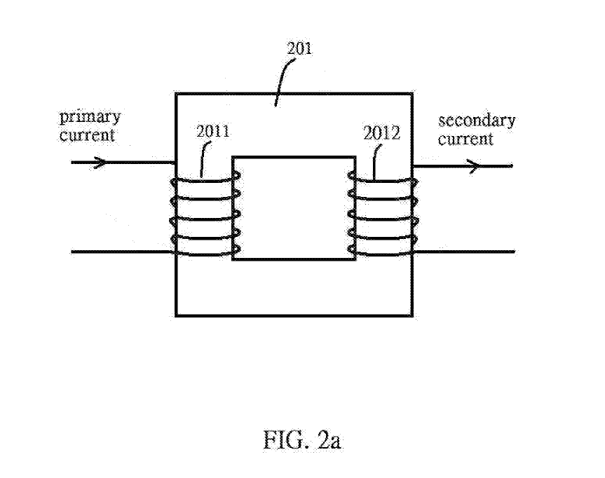

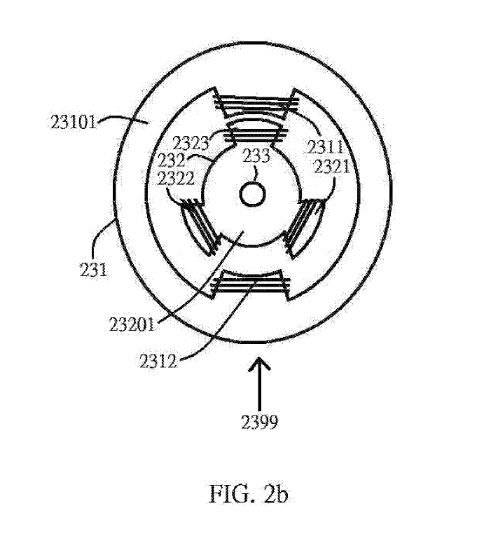

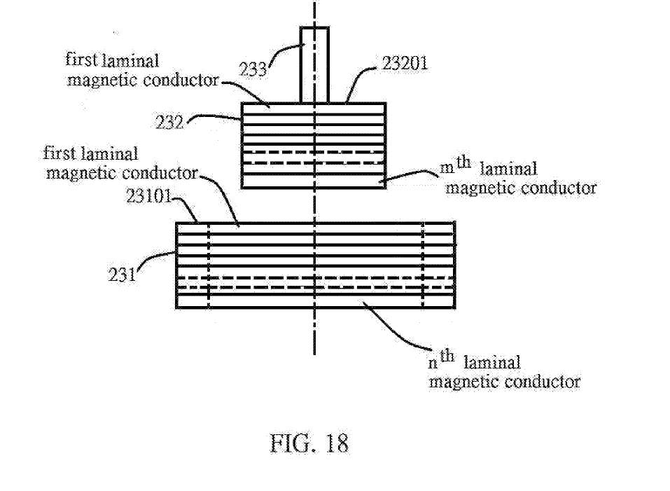

FIG. 18 has shown an inventive stator multiple-laminal-magnetic-conductor magnetic core 231 and rotor multiple-laminal-magnetic-conductor magnetic core 232 in side view referred to the stator core and the rotor core of the electric motor core shown in FIG. 2b.

The stator multiple-laminal-magnetic-conductor magnetic core 231 has n magnetic conductors. The n is an integer larger than 1. Each of the n magnetic conductors of the stator multiple-laminal-magnetic-conductor magnetic core 231 is in laminal shape, and the n laminal magnetic conductors of the stator multiple-laminal-magnetic-conductor magnetic core 231 are piled up by laying a laminal magnetic conductor on another laminal magnetic conductor, and the n laminal magnetic conductors have different saturation levels from each other aiming to produce saturations one by one in a row by a first magnetization such as a first current with a specific waveform flowing through a stator conductive coil winding around the n laminal magnetic conductors or a neighboring first magnetic field in a magnetically interactive distance in phase with at least one of the n laminal magnetic conductors. The n laminal magnetic conductors of the stator multiple-laminal-magnetic-conductor magnetic core 231 may be different from each other in shape, material, thickness and conductivity, for example, they can be conductive or non-conductive.

The stator multiple-laminal-magnetic-conductor magnetic core 231 has at least an unsaturable laminal magnetic conductor by the first magnetization such that the stator conductive coil has a non-zero inductance by the first magnetization.

The stator multiple-laminal-magnetic-conductor magnetic core 231 still allows a plurality of laminal magnetic conductors to have a same saturation level, and if it is the case, then the plurality of laminal magnetic conductors having the same saturation level to produce saturations at the same time by a magnetization can be treated as one laminal magnetic conductor.

The rotor multiple-laminal-magnetic-conductor magnetic core 232 has m magnetic conductors. The m is an integer larger than 1. Each of the m magnetic conductors of the rotor multiple-laminal-magnetic-conductor magnetic core 232 is in laminal shape, and the m laminal magnetic conductors of the rotor multiple-laminal-magnetic-conductor magnetic core 232 are piled up by laying a laminal magnetic conductor on another laminal magnetic conductor and the m laminal magnetic conductors have different saturation levels from each other aiming to produce saturations one by one in a row by a second magnetization such as a second current with a specific waveform flowing through a rotor conductive coil winding around the m laminal magnetic conductors or a neighboring second magnetic field in a magnetically interactive distance in phase with at least one of the m laminal magnetic conductors. The m laminal magnetic conductors of the rotor multiple-laminal-magnetic-conductor magnetic core 232 may be different from each other in shape, material, thickness and conductivity, for example, they can be conductive or non-conductive.

The rotor multiple-laminal-magnetic-conductor magnetic core 232 has at least an unsaturable laminal magnetic conductor by the second magnetization such that the rotor conductive coil has a non-zero inductance by the second magnetization.

The rotor multiple-laminal-magnetic-conductor magnetic core 232 still allows a plurality of laminal magnetic conductors to have a same saturation level, and if it is the case, then the plurality of laminal magnetic conductors having the same saturation level to produce saturations at the same time by a magnetization can be treated as one laminal magnetic conductor.

The m and n are integers larger than 1 and they can be identical. The first current of the first magnetization can be the second current of the second magnetization. The first magnetic field can be the second magnetic field.

The current flowing through the stator conductive coil and rotor conductive coil respectively magnetizes the stator multiple-laminal-magnetic-conductor magnetic core 231 and the rotor multiple-laminal-magnetic-conductor magnetic core 232 and the current saturates at least a portion of the n laminal magnetic conductors of the stator multiple-laminal-magnetic-conductor magnetic core 231 and the m laminal magnetic conductors of the rotor multiple-laminal-magnetic-conductor magnetic core 232 to cause their correspondent inductance drops such that the current pulled from power source will become bigger and bigger as revealed by the embodiment of FIG. 7 and higher frequency opertion capability also increases as revealed above in the embodiment of FIGS. 8a and 8b. Growing-larger current brings larger torque between the stator multiple-laminal-magnetic-conductor magnetic core 231 and the rotor multiple-laminal-magnetic-conductor magnetic core 232 as revealed by equation

$$τ = \frac{1}{2} {i}^{2} \frac{d L ( θ )}{d θ}$$

in the information background section. Inductance drops bring higher frequency opertion capability as revealed by the current-time characteristic shown in FIGS. 8a and 8b.

The embodiment of FIG. 18 referred to FIG. 2b has shown the inventive electric motor core can provide bigger torque and has higher frequency opertion capability. If two adjacent laminal magnetic conductors of the stator multiple-laminal-magnetic-conductor magnetic core 231 and the rotor multiple-laminal-magnetic-conductor magnetic core 232 are conductive, then an electrical isolator can be disposed between the two adjacent conductive magnetic conductors for electrically isolating them against forming into a bigger size conductor advantaging the development of so called “Eddy current”.

If a laminal magnetic conductor of the stator multiple-laminal-magnetic-conductor magnetic core 231 and the rotor multiple-laminal-magnetic-conductor magnetic core 232 has a thickness smaller than its associated penetration depth of skin effect, then the “Eddy current” problem can be also reduced because “Eddy current” has less space to stay. Thin laminal magnetic conductor and electrical isolator can be respectively formed by spraying or coating their associated materials on another lamina.

If all the laminal magnetic conductors of the stator multiple-laminal-magnetic-conductor magnetic core 231 and the rotor multiple-laminal-magnetic-conductor magnetic core 232 are non-conductive, then the induced so called “Eddy current” problem can be further reduced.

A magnetic conductor in saturation produces heat so that the heat dissipation may be considered. At least a portion of a side of a laminal magnetic conductor of the stator multiple-laminal-magnetic-conductor magnetic core 231 and the rotor multiple-laminal-magnetic-conductor magnetic core 232 facing adjacent laminal magnetic conductor may have an area for contacting cooling matter such as air or cooling fluid for better heat dissipation capability as revealed by the embodiment of FIG. 13.

A laminal magnetic conductor in saturation produces heat so that the easiest saturable laminal magnetic conductor or a laminal magnetic conductor with the lowest saturation level can be disposed at a best heat dissipation location such as the top or the bottom lamina of the stator multiple-laminal-magnetic-conductor magnetic core 231 and the rotor multiple-laminal-magnetic-conductor magnetic core 232 having more area for contacting cooling matter such as air or cooling fluid. A magnetic conductor with the second lowest saturation level can be disposed at a lamina next to the top or bottom lamina and so on the logic.

FIG. 18 has shown an inventive stator multiple-laminal-magnetic-conductor magnetic core 231 and rotor multiple-laminal-magnetic-conductor magnetic core 232 in side view referred to the stator core and the rotor core of the electric generator core in top view shown in FIG. 2b.

The stator multiple-laminal-magnetic-conductor magnetic core 231 has n magnetic conductors. The n is an integer larger than 1. Each of the n magnetic conductors of the stator multiple-laminal-magnetic-conductor magnetic core 231 is in laminal shape, and the n laminal magnetic conductors of the stator multiple-laminal-magnetic-conductor magnetic core 231 are piled up by laying a laminal magnetic conductor on another laminal magnetic conductor and the n laminal magnetic conductors have different saturation levels from each other for producing saturations one by one in a row by a magnetization. A stator conductive coil winds around the n laminal magnetic conductors of the stator multiple-laminal-magnetic-conductor magnetic core 231. The n laminal magnetic conductors of the stator multiple-laminal-magnetic-conductor magnetic core 231 may be different from each other in shape, material, thickness and conductivity, for example, they can be conductive or non-conductive.

The stator multiple-laminal-magnetic-conductor magnetic core 231 still allows a plurality of laminal magnetic conductors to have a same saturation level, and if it is the case, then the plurality of laminal magnetic conductors having the same saturation level to produce saturations at the same time by a magnetization can be treated as one laminal magnetic conductor.

The rotor multiple-laminal-magnetic-conductor magnetic core 232 has m magnetic conductors. The m is an integer larger than 1. Each of the m magnetic conductors of the rotor multiple-laminal-magnetic-conductor magnetic core 232 is in laminal shape, and the m laminal magnetic conductors of the rotor multiple-laminal-magnetic-conductor magnetic core 232 are piled up by laying a laminal magnetic conductor on another laminal magnetic conductor and the m laminal magnetic conductors have different saturation levels from each other for producing saturations one by one in a row by a magnetization. A rotor conductive coil winds around the m laminal magnetic conductors of the rotor multiple-laminal-magnetic-conductor magnetic core 232. The m laminal magnetic conductors of the rotor multiple-laminal-magnetic-conductor magnetic core 232 may be different from each other in shape, material, thickness and conductivity, for example, they can be conductive or non-conductive.

The rotor multiple-laminal-magnetic-conductor magnetic core 232 still allows a plurality of laminal magnetic conductors to have a same saturation level, and if it is the case, then the plurality of laminal magnetic conductors having the same saturation level to produce saturations at the same time by a magnetization can be treated as one laminal magnetic conductor.

If an input current with a specific waveform flows through the stator conductive coil or the rotor conductive coil for magnetizing its winding magnetic core and a relative motion takes place between the stator multiple-laminal-magnetic-conductor magnetic core 231 and the rotor multiple-laminal-magnetic-conductor magnetic core 232, then an output current will be induced on the stator conductive coil or the rotor conductive coil not being flowed by the input current. For example, if an input current flowing through the rotor conductive coil and rotating the rotor multiple-laminal-magnetic-conductor magnetic core 232, then an output current will be induced on the stator conductive coil.

For the purpose of convenience, the stator conductive coil or the rotor conductive coil being flowed by the input current can be called “input-current coil” in the present invention and the stator conductive coil or the rotor conductive coil not being flowed by the input current can be called “output-current coil” in the present invention. The stator multiple-laminal-magnetic-conductor magnetic core 231 or the rotor multiple-laminal-magnetic-conductor magnetic core 232 wound by the “input-current coil” is called “input-current core” and the stator multiple-laminal-magnetic-conductor magnetic core 231 or the rotor multiple-laminal-magnetic-conductor magnetic core 232 wound by the “output-current coil” is called “output-current core” in the present invention.

The input current will saturate the laminal magnetic conductors of the “input-current core” to cause the inductance drops of the “input-current coil” resulting in growing-larger-and-larger input current. The input-current core has at least an unsaturable laminal magnetic conductor by the input current flowing through the “input-current coil” such that the “input-current coil” has a non-zero inductance by the input current flowing through the “input-current coil” promising more stored magnetic energy converted by the growing-larger-and-larger input current as revealed by the embodiment of FIG. 7.

The output current induced on the “output-current coil” will saturate the laminal magnetic conductors of the “output-current core” to cause the inductance drops of the “output-current coil” resulting in a growing-larger-and-larger output current for driving loading.

According to equation

$$\begin{matrix}Z = j {X}_{L} \\ = j2π fL\end{matrix}$$

the inductance drop L allows the frequency f to increase to keep the same impedance Z. For example, according to the equation, if L drops to a non-zero L/a for a>1, then frequency f has chance to increase to af to keep the same impedance Z. The af can be contributed by the modulation of a frequency of the specific waveform of the input current and a frequency of the relative motion between the stator multiple-laminal-magnetic-conductor magnetic core 231 and the rotor multiple-laminal-magnetic-conductor magnetic core 232 because the total frequency after the modulation is the multiplication of the frequency of the input current and the frequency of the relative motion. The modulation of the frequency of the input current and the frequency of the relative motion between the stator multiple-laminal-magnetic-conductor magnetic core 231 and the rotor multiple-laminal-magnetic-conductor magnetic core 232 produces an induced output current is in a multi-waveform. An output current in multi-waveform provides better impedance matching capability.

According to the embodiment of FIG. 18, the inductance drops of the “input-current coil” and “output-current coil” by the saturations and the modulation of the frequency of the input current and the frequency of the relative motion between the stator multiple-laminal-magnetic-conductor magnetic core 231 and the rotor multiple-laminal-magnetic-conductor magnetic core 232 promise an growing-larger output current in a multi-waveform and the electric generator has higher frequency operation capability as revealed by the embodiemnt of FIGS. 8a and 8b.

The m and n are integers larger than 1 and they can be identical. The first current of the first magnetization can be the second current of the second magnetization. If two adjacent laminal magnetic conductors of the stator multiple-laminal-magnetic-conductor magnetic core 231 and the rotor multiple-laminal-magnetic-conductor magnetic core 232 are conductive, then an electrical isolator can be disposed between the two adjacent conductive magnetic conductors for electrically isolating them against forming into a bigger size conductor advantaging the development of so called “Eddy current”.

If a laminal magnetic conductor of the stator multiple-laminal-magnetic-conductor magnetic core 231 and the rotor multiple-laminal-magnetic-conductor magnetic core 232 has a thickness smaller than its associated penetration depth of skin effect, then the “Eddy current” problem can be also reduced because “Eddy current” has less space to stay. Thin laminal magnetic conductor and electrical isolator can be respectively formed by spraying or coating their associated materials on another lamina.

If all the laminal magnetic conductors of the stator multiple-laminal-magnetic-conductor magnetic core 231 and the rotor multiple-laminal-magnetic-conductor magnetic core 232 are non-conductive, then the induced so called “Eddy current” problem can be further reduced.

A magnetic conductor in saturation produces heat so that the heat dissipation may be considered. At least a portion of a side of a laminal magnetic conductor of the stator multiple-laminal-magnetic-conductor magnetic core 231 and the rotor multiple-laminal-magnetic-conductor magnetic core 232 facing adjacent laminal magnetic conductor may have an area for contacting cooling matter such as air or cooling fluid for better heat dissipation capability as revealed by the embodiment of FIG. 13.

A laminal magnetic conductor in saturation produces heat so that the easiest saturable laminal magnetic conductor or a laminal magnetic conductor with the lowest saturation level can be disposed at a best heat dissipation location such as the top or the bottom lamina of the stator multiple-laminal-magnetic-conductor magnetic core 231 and the rotor multiple-laminal-magnetic-conductor magnetic core 232 having more area for contacting cooling matter such as air or cooling fluid. A magnetic conductor with the second lowest saturation level can be disposed at a lamina next to the top or bottom lamina and so on the logic.

1. A magnetic core for forming an inductor, comprising:
a plurality of magnetic conductors having different saturation levels from each other to produce saturations one by one in a row by a magnetization as a current flowing through a conductive coil winding around the plurality of magnetic conductors or a magnetic field within a magnetically interactive distance in phase with at least one of the plurality of magnetic conductors resulting in the variations of inductance of the conductive coil.

2. The magnetic core of claim 1, wherein each of the plurality of magnetic conductors is in laminal shape, and the plurality of laminal magnetic conductors are piled up by laying a laminal magnetic conductor on another laminal magnetic conductor.

3. The magnetic core of claim 1, further comprising at least an electrical isolator, wherein the electrical isolator is disposed between two adjacent conductive magnetic conductors for electrically isolating the two adjacent conductive magnetic conductors against the development of the “Eddy current”.

4. The magnetic core of claim 1, further comprising at least an electrical isolator, wherein the electrical isolator is disposed between two adjacent conductive magnetic conductors for electrically isolating the two adjacent conductive magnetic conductors against the development of “Eddy current”, and each of the plurality of magnetic conductors and the electrical isolator are in laminal shape, and the plurality of laminal magnetic conductors and the laminal electrical isolator are piled up by laying a lamina on another lamina.

5. The magnetic core of claim 2, wherein each laminal magnetic conductor has a thickness smaller than its associated penetration depth of skin effect against the development of the Eddy current.

6. The magnetic core of claim 3, wherein each laminal magnetic conductor has a thickness smaller than its associated penetration depth of skin effect against the development of the Eddy current.

7. The magnetic core of claim 4, wherein each lamina has a thickness smaller than its associated penetration depth of skin effect against the development of the Eddy current.

8. The magnetic core of claim 2, wherein at least a portion of a side of a magnetic conductor facing adjacent magnetic conductor has an area exposed for cooling matter contact for heat dissipation.

9. The magnetic core of claim 4, wherein at least a portion of a side of a magnetic conductor facing adjacent magnetic conductor has an area exposed for cooling matter contact for heat dissipation.

10. The magnetic core of claim 5, wherein at least a portion of a side of a magnetic conductor facing adjacent magnetic conductor has an area exposed for cooling matter contact for heat dissipation.

11. The magnetic core of claim 5, wherein a laminal magnetic conductor of the plurality of laminal magnetic conductors with the lowest saturation level is disposed as a top or a bottom lamina, and a laminal magnetic conductor of the plurality of laminal magnetic conductors with the second lowest saturation level is disposed next to the top or bottom lamina, and so on.

12. The magnetic core of claim 6, wherein a laminal magnetic conductor of the plurality of laminal magnetic conductors with the lowest saturation level is disposed as a top or a bottom lamina, and a laminal magnetic conductor of the plurality of laminal magnetic conductors with the second lowest saturation level is disposed next to the top or bottom lamina, and so on.

13. The magnetic core of claim 5, wherein the plurality of laminal magnetic conductors have at least an unsatuable magnetic conductor by the magnetization such that the conductive coil has a non-zero inductance by the magnetization.

14. The magnetic core of claim 6, wherein the plurality of laminal magnetic conductors have at least an unsatuable magnetic conductor by the magnetization such that the conductive coil has a non-zero inductance by the magnetization.

15. The magnetic core of claim 5, wherein the plurality of laminal magnetic conductors have all satuable magnetic conductors by the magnetization such that the conductive coil has a zero inductance by the magnetization.

16. The magnetic core of claim 6, wherein the plurality of laminal magnetic conductors have all satuable magnetic conductors by the magnetization such that the conductive coil has a zero inductance by the magnetization.

17. An inductor, comprising:
a plurality of magnetic conductors; and
a conductive coil winding around the plurality of magnetic conductors;
wherein the plurality of magnetic conductors having different saturation levels from each other to produce saturations one by one in a row by a magnetization as a current flowing through the conductive coil winding around the plurality of magnetic conductors or a magnetic field within a magnetically interactive distance in phase with at least one of the plurality of magnetic conductors such that the conductive coil has dropping inductances by the magnetization.

18. The inductor of claim 17, wherein each of the plurality of magnetic conductors is in laminal shape, and the plurality of laminal magnetic conductors are piled up by laying a laminal magnetic conductor on another laminal magnetic conductor.

19. The inductor of claim 17, further comprising at least an electrical isolator, wherein the electrical isolator is disposed between two adjacent conductive magnetic conductors for electrically isolating the two adjacent conductive magnetic conductors against the development of the “Eddy current”.

20. The inductor of claim 17, further comprising at least an electrical isolator, wherein the electrical isolator is disposed between two adjacent conductive magnetic conductors for electrically isolating the two adjacent conductive magnetic conductors against the development of “Eddy current”, and each of the plurality of laminal magnetic conductors and the electrical isolator are in laminal shape, and the plurality of laminal magnetic conductors and the electrical isolator are piled up by laying a lamina on another lamina.

21. The inductor of claim 18, wherein each laminal magnetic conductor has a thickness smaller than its associated penetration depth of skin effect against the development of the Eddy current.

22. The inductor of claim 18, wherein the plurality of laminal magnetic conductors have all saturable magnetic conductors by the magnetization such that the conductive coil has a zero inductance by the magnetization.

23. The inductor of claim 18, wherein at least one of the plurality of laminal magnetic conductors is an unsaturable laminal magnetic conductor by the magnetization such that the conductive coil has a non-zero inductance by the magnetization.

24. A switching circuit, comprising:
an electrical power source;
a first inductor, comprising a plurality of magnetic conductors and a conductive coil winding around the plurality of magnetic conductors; and
a frequency modulator for providing frequency-modulation;
wherein the electrical power source, the first inductor and the frequency modulator are electrically connected in series with each other, and the plurality of magnetic conductors of the first inductor have different saturations from each other for producing saturations one by one in a row by a magnetization as a current from the electrical power source flowing through the conductive coil winding around the plurality of magnetic conductors of the first inductor or a magnetic field in a magnetically interactive distance with at least one of the plurality of magnetic conductors of the first inductor such that an inductance of the conductive coil of the first inductor drops by the magnetization.

25. The switching circuit of claim 24, wherein each of the plurality of magnetic conductors of the first inductor is in laminal shape, and the plurality of laminal magnetic conductors are piled up by laying a laminal magnetic conductor on another laminal magnetic conductor.

26. The switching circuit of claim 24, wherein at least one of the plurality of magnetic conductors of the first inductor is an unsaturable magnetic conductor by the magnetization such that the conductive coil of the first inductor has a non-zero inductance by the magnetization to provide a safe impedance between the electrical power source and the frequency modulator.

27. The switching circuit of claim 25, wherein at least one of the plurality of magnetic conductors of the first inductor is an unsaturable magnetic conductor by the magnetization such that the conductive coil of the first inductor has a non-zero inductance by the magnetization to provide a safe impedance between the electrical power source and the frequency modulator.

28. The switching circuit of claim of 24, further comprising a loading electrically connected to a high side of the first inductor, a low side of the first inductor, a high side of the frequency modulator or a low side of the frequency modulator.

29. The switching circuit of claim of 24, further comprising a loading and a second inductor forming a transformer with the first inductor for driving the loading.

30. The switching circuit of claim of 25, further comprising a loading electrically connected to a high side of the first inductor, a low side of the first inductor, a high side of the frequency modulator or a low side of the frequency modulator.

31. The switching circuit of claim of 25, further comprising a loading and a second inductor forming a transformer with the first inductor for driving the loading.

32. The switching circuit of claim of 26, further comprising a loading electrically connected to a high side of the first inductor, a low side of the first inductor, a high side of the frequency modulator or a low side of the frequency modulator.

33. A transformer core, comprising:
a primary magnetic core; and
a secondary magnetic core having a plurality of magnetic conductors;
wherein the primary magnetic coil and the plurality of magnetic conductors of the secondary magnetic core are in a magnetically interative distance with each other such that an input current flowing through a primary conductive coil winding around the primary magnetic core produces a magnetic flux at least a portion of which passes through a secondary conductive coil winding around the plurality of magnetic conductors of the secondary magnetic core to induce an output current on the secondary conductive coil, and each of the plurality of magnetic conductors of the secondary magnetic core is in laminal shape, and the plurality of laminal magnetic conductors are piled up by laying a laminal magnetic conductor on another laminal magnetic conductor, and the plurality of laminal magnetic conductors have different saturation levels from each other for producing saturations one by one in a row by a magnetization as the output current induced on the secondary conductive coil winding around the plurality of laminal magnetic conductors of the secondary magnetic core or a magnetic field in a magnetically interactive distance with the plurality of laminal magnetic conductors of the secondary magnetic core such that the inductance of the second conductive coil drops resulting in increasing the output current.

34. The transformer core of claim 33, wherein the primary magnetic core and the plurality of magnetic conductors of the secondary magnetic core form a closed magnetic loop.

35. The transformer core of claim 34, wherein the plurality of laminal magnetic conductors of the secondary magnetic core have at least an unsaturable magnetic conductor by the magne tization such that the secondary conductive coil has a non-zero inductance by the magnetization.

36. The transformer of claim 34, wherein the plurality of laminal magnetic conductors are all saturable magnetic conductors by the magnetization such that the secondary conductive coil has zero inductance by the magnetization.

37. An electric motor core, comprising:
a stator core having a plurality of magnetic conductors, wherein the plurality of magnetic conductors of the stator core have different saturation levels from each other, and each of the plurality of magnetic conductors of the stator core is in laminal shape, and the plurality of laminal magnetic conductors of the stator core are piled up by laying a laminal magnetic conductor on another laminal magnetic conductor, and at least one of the plurality of laminal magnetic conductors of the stator core is an unsaturable magnetic conductor by a first magnetization as a first input with a specific waveform current flowing through a stator conductive coil winding around the plurality of laminal magnetic conductors of the stator core or a magnetic field in a magnetically interactive distance in phase with at least one of the plurality of laminal magnetic conductors of the stator core such that the inductance of the stator conductive coil drops to a non-zero number by the first magnetization resulting in increasing the first input current; and
a rotor core having a plurality of magnetic conductors, wherein the plurality of magnetic conductors of the rotor core have different saturation levels from each other, and each of the plurality of magnetic conductors of the rotor core is in laminal shape, and the plurality of laminal magnetic conductors of the rotor core are piled up by laying a laminal magnetic conductor on another laminal magnetic conductor, and at least one of the plurality of laminal magnetic conductors of the rotor core is an unsaturable magnetic conductor by a second magnetization as a second input current with a specific waveform flowing through a rotor conductive coil winding around the plurality of laminal magnetic conductors of the rotor core or a magnetic field in a magnetically interactive distance in phase with at least one of the plurality of laminal magnetic conductors of the rotor core such that the inductance of the rotor conductive coil drops to a non-zero number by the second magnetization resulting in increasing the second input current, the increasing of the first current and the second current produce bigger torque between the stator core and the motor core, and the inductance drop of the stator conductive coil and the inductance drop of the rotor conductive coil increase higher frequency operation capability of the electric motor core.

38. The electric motor core of claim 37, wherein each laminal magnetic conductor of the stator core and the rotor core has a thickness smaller than its associated penetration depth of skin effect against the development of Eddy current.

39. The electric motor core of claim 37, wherein the first input current of the first magnetization is the second input current of the second magnetization.

40. An electric generator core, comprising:
a stator core having a plurality of magnetic conductors; and
a rotor core having a plurality of magnetic conductors;
wherein each of the plurality of magnetic conductors of the stator core is in laminal shape, and the plurality of laminal magnetic conductors of the stator core are piled up by laying a laminal magnetic conductor on another laminal magnetic conductor, and the plurality of magnetic conductors of the stator core have different saturation levels from each other, and each of the plurality of magnetic conductors of the rotor core is in laminal shape, and the plurality of laminal magnetic conductors of the rotor core are piled up by laying a laminal magnetic conductor on another laminal magnetic conductor, and the plurality of magnetic conductors of the rotor core have different saturation levels from each other, and an input current with specific waveform flowing through a stator conductive coil winding around the stator core or a rotor conductive coil winding around the rotor core to magnetize its winding core and a relative motion between the stator core and the rotor core causes an output current induced on the stator conductive coil or the rotor conductive coil not being flowed by the input current, and the stator core or the rotor core magnetized by the input current has at least an unsaturable laminal magnetic conductor by the input current such that the stator conductive coil or the rotor conductive coil being flowed by the input current has a non-zero inductance by the input current flowing through the stator conductive coil or the rotor conductive coil, and the input current flowing through the stator conductive coil or the rotor conductive coil saturates its winding magnetic conductors one by one in a row causes an inductance of the stator conductive coil or the rotor conductive coil being flowed by the input current to drop to a non-zero number resulting in increasing the input current, and an output current induced on the stator conductive coil or the rotor conductive coil not being flowed by the input current saturates its winding magnetic conductors one by one in a row causes an inductance of the stator conductive coil or the rotor conductive coil being flowed by the induced output current to drop resulting in increasing the output current.

41. The electric generator core of claim 40, wherein a frequency of specific waveform of the input current modulates with a frequency of the relative motion between the stator core and the rotor core to produce the output current in a multi-waveform.
